(19) United States
(12) Patent Application Publication
(10) Pub. No.: US 2014/0110153 A1
(43) Pub. Date: Apr. 24, 2014

(54) WIRING BOARD AND METHOD FOR MANUFACTURING THE SAME

(71) Applicants: Takafumi Kashiwagi, Osaka (JP); Eri Kamada, Nara (JP); Yoshiki Okushima, Osaka (JP); Hideki Niimi, Osaka (JP); Ayako Iwasawa, Osaka (JP); Tadashi Nakamura, Mie (JP)

(72) Inventors: Takafumi Kashiwagi, Osaka (JP); Eri Kamada, Nara (JP); Yoshiki Okushima, Osaka (JP); Hideki Niimi, Osaka (JP); Ayako Iwasawa, Osaka (JP); Tadashi Nakamura, Mie (JP)

(73) Assignee: PANASONIC CORPORATION, Osaka (JP)

(21) Appl. No.: 13/995,088

(22) PCT Filed: Jan. 11, 2013
(86) PCT No.: PCT/JP2013/000077

§ 371 Date: Jun. 17, 2013

(30) Foreign Application Priority Data
Jan. 17, 2012 (JP) 2012-006694
Jan. 24, 2012 (JP) 2012-011883
Aug. 23, 2012 (JP) 2012-183958

(51) Int. Cl. H05K 1/09; H05K 3/00; H05K 1/11

(52) U.S. Cl. CPC H05K 1/092; H05K 1/115; H05K 3/0094
USPC 174/251; 29/846

(57) ABSTRACT

A wiring board includes an insulating resin layer, wirings, and a via-hole conductor. The wirings are disposed through the insulating resin layer therebetween and formed of copper foils. The via-hole conductor penetrates through the insulating resin layer and electrically connects the wirings together. The via-hole conductor includes a resin portion and a metal portion containing copper, tin, and bismuth. The metal portion includes a first metal region including a link of copper particles, a second metal region including, as a main component, at least one of tin, a tin-copper alloy, and a tin-copper intermetallic compound, and a third metal region including bismuth as a main component. The copper particles partially include a plane-to-plane contact with a roughened surface of the copper foil, and the second metal region is partially formed on a surface of the link and on the roughened surface of the copper foil.

### TECHNICAL FIELD

The present invention relates to a wiring board formed of wirings disposed through an insulating resin layer therebetween, and connected to one another by via-hole conductors serving as an interlayer connection therebetween. Specifically, the present invention relates to improving connection reliability by way of low-resistance via-hole conductors to realize fine patterning of wiring and a smaller via diameter.

### BACKGROUND ART

A multilayer wiring board, which is obtained by connecting wirings disposed through an insulating resin layer therebetween and connected to one another by means of interlayer connections, is known. As a way to create such an interlayer connection, via-hole conductors are well-known. The via-hole conductors are formed by filling a conductive paste in holes created in the insulating resin layer. Also another via-hole conductors which are formed by filling, in place of a conductive paste, metal particles containing copper (Cu), and then fixing the metal particles to one another with use of an intermetallic compound are known.

Specifically, for example, PTL 1 discloses via-hole conductors having a matrix-domain structure, in which domains of copper particles are interspersed in a CuSn compound matrix.

Also, PTL 2 discloses, as a sinterable composition for forming via-hole conductors, a composition including a high-melting-point particle-phase material that includes Cu and a low-melting-point material selected from metals such as tin (Sn) and tin alloys. Such a composition is sintered in the presence of a liquid phase or a transient liquid phase.

Also, PTL 3 discloses a via-hole conductor material in which an alloy layer with a solidus temperature of 250° C. or higher is formed on outer surfaces of copper particles. Such an alloy layer is formed by heating a conductive paste containing tin-bismuth (Bi) metal particles and copper particles at a temperature equal to or higher than a melting point of the tin-bismuth (Bi) metal particles. In such a via-hole conductor material, interlayer connection is achieved by the alloy layers joined to one another at a solidus temperature of 250° C. or higher. This prevents the alloy layers from melting even during heat cycle tests and reflow resistance tests. Accordingly, such a material is expected as achieving high connection reliability.

Further, PTL 4 discloses a laminated circuit board using a surface-roughened copper foil having a surface roughness Rz ranging from 0.5 μm to 10 μm, which is formed by etching a surface of an electrolytic copper foil, and describes that a conductive paste containing a low-melting-point metal is used for the laminated circuit board.

### CITATION LIST

### Patent Literatures

PTL 1: Unexamined Japanese Patent Publication No. 2000-049460
PTL 2: Unexamined Japanese Patent Publication No. H10-007933
PTL 3: Unexamined Japanese Patent Publication No. 2002-094242
PTL 4: Unexamined Japanese Patent Publication No. 2006-269706

### SUMMARY OF THE INVENTION

The present invention is directed to a multilayer wiring board in which interlayer connections are made by a via-hole conductor having low resistance and high connection reliability, and which can cope with Pb free needs. Further, according to the multilayer wiring board, by reducing connection resistance between wiring and the via-hole conductor in the multilayer wiring board and increasing connection strength, the wiring is finely patterned, a diameter of the via-hole conductor can be reduced, and high connection reliability is provided.

A wiring board according to the present invention includes an insulating resin layer, wirings, and a via-hole conductor. The wirings are disposed through the insulating resin layer therebetween and each of the wirings is formed of a copper foil. The via-hole conductor penetrates through the insulating resin layer and electrically connects the wirings together. The via-hole conductor includes a resin portion and a metal portion containing copper, tin, and bismuth. The metal portion includes a first metal region including a link of copper particles, a second metal region including, as a main component, at least one of tin, a tin-copper alloy, and a tin-copper intermetallic compound, and a third metal region including bismuth as a main component. A weight ratio of composition (Cu:Sn:Bi) of copper, tin, and bismuth in the metal portion falls in a quadrilateral with vertices of A (0.37:0.567:0.063), B (0.22:0.3276:0.4524), C (0.79:0.09:0.12), and D (0.89:0.10:0.01) in a ternary plot. A surface of the copper foil in contact with the via-hole conductor is a roughened surface having skewness of 0 or less of a roughness curve defined by ISO 4287-1997. The copper particles are partially in plane-to-plane contact with the roughened surface of the copper foil. The second metal region is partially formed on a surface of the link of the copper particles and on the roughened surface of the copper foil.

Further, according to a method for manufacturing a wiring board of the present invention, first, a through-hole is formed by perforating a prepreg covered with protective films, from an outer side of one of the protective films. Next, the through-hole is filled with a via paste. Protruding portions that are the via paste partially protruding from the through-hole are exposed on the surface by removing the protective films after filling the via paste into the through-hole. Next, copper foils each including a roughened surface having skewness Rsk of 0 or less of a roughness curve defined by ISO 4287-1997 are disposed on surfaces of the prepreg so as to cover the protruding portions with the each roughened surface. The copper foils are compression-bonded onto the surface of the prepreg after the copper foils are disposed on the surfaces of the prepreg. Then, the copper foils, the prepreg, and the via paste are heated while the copper foils are compression-bonded onto the surfaces of the prepreg. Next, the copper foils are patterned to form wirings. The via paste includes copper particles, tin-bismuth solder particles, and a thermally curable resin. A weight ratio of composition, which is copper:tin:bismuth falls in a quadrilateral with vertices of A (0.37:0.567:0.063), B (0.22:0.3276:0.4524), C (0.79:0.09:0.12), and D (0.89:0.10:0.01) in a ternary plot. A link of the copper particles is formed, and a plane-to-plane contact portion is formed between part of the copper particles and the copper foil, by compression-bonding the copper foils onto the surfaces of the prepreg. Further, when the copper foils, the prepreg, and the via paste are heated, the solder particles are melted by heating them at a temperature equal to or higher than a eutectic temperature of the solder particles. With this procedure, a first metal region including the link; a second metal region including, as a main component, at least one of tin, a tin-copper alloy, and a tin-copper intermetallic compound, and formed between a surface of the link and the roughened surface; and a third metal region including bismuth as a main component, are formed.

According to the present invention, the copper particles included in the via-hole conductor of the wiring board make plane-to-plane contact with one another to form the link, and further the copper particles and the roughened surface forming the wirings are in plane-to-plane contact with each other. With this structure, low-resistance conduction paths are formed, and an interlayer connection having low resistance can be realized. Further, since the surface of the link between the copper particles and the roughened surface of the copper foil have the second metal region which is harder than the copper particles, bonding among the link, and bonding of the copper particles and the copper foil are strengthened. Accordingly, this increases an electrical connection reliability.

### BRIEF DESCRIPTION OF DRAWINGS

FIG. 1A is a schematic cross sectional view of a multilayer wiring board according to an embodiment of the present invention.

FIG. 1B is an enlarged schematic cross sectional view illustrating a via-hole conductor and a vicinity thereof illustrated in FIG. 1A.

FIG. 2 is an explanatory drawing illustrating a conductive path created by one of links each formed by copper particles coming into plane-to-plane contact with one another in a first metal region including a number of copper particles in the via-hole conductor illustrated in FIG. 1B.

FIG. 3A is a cross sectional view illustrating one example of a method for manufacturing the multilayer wiring board illustrated in FIG. 1A.

FIG. 3B is a cross sectional view subsequent to a step illustrated in FIG. 3A, illustrating one example of the method for manufacturing the multilayer wiring board.

FIG. 3C is a cross sectional view subsequent to a step illustrated in FIG. 3B, illustrating one example of the method for manufacturing the multilayer wiring board.

FIG. 3D is a cross sectional view subsequent to a step illustrated in FIG. 3C, illustrating one example of the method for manufacturing the multilayer wiring board.

FIG. 4A is a cross sectional view subsequent to a step illustrated in FIG. 3D, illustrating one example of the method for manufacturing the multilayer wiring board.

FIG. 4B is a cross sectional view subsequent to a step illustrated in FIG. 4A, illustrating one example of the method for manufacturing the multilayer wiring board.

FIG. 4C is a cross sectional view subsequent to a step illustrated in FIG. 4B, illustrating one example of the method for manufacturing the multilayer wiring board.

FIG. 5A is a cross sectional view subsequent to a step illustrated in FIG. 4C, illustrating one example of the method for manufacturing the multilayer wiring board.

FIG. 5B is a cross sectional view subsequent to a step illustrated in FIG. 5A, illustrating one example of the method for manufacturing the multilayer wiring board.

FIG. 5C is a cross sectional view subsequent to a step illustrated in FIG. 5B, illustrating one example of the method for manufacturing the multilayer wiring board.

FIG. 6 is a ternary plot illustrating compositions of Cu, Sn, and Bi of a metallic portion included in a via-hole conductor (via paste) according to the embodiment of the present invention.

FIG. 7A is a schematic cross sectional view illustrating a state prior to compressing the via paste filled in a through-hole of a prepreg according to the embodiment of the present invention.

FIG. 7B is a schematic cross sectional view illustrating a state after compressing the via paste filled in the through-hole of the prepreg according to the embodiment of the present invention.

FIG. 8A is an observed image, viewed through an electron microscope (SEM), of a cross section of a via-hole conductor of the multilayer wiring board according to one example of the embodiment of the present invention.

FIG. 8B is a schematic diagram of FIG. 8A.

FIG. 9A is an enlarged view of FIG. 8A.

FIG. 9B is a schematic diagram of FIG. 9A.

FIG. 10A is an observed image, viewed through the SEM, of an etching surface of the copper foil used for the multilayer wiring board according to one example of the embodiment of the present invention.

FIG. 10B is an enlarged view of FIG. 10A.

FIG. 11A is an observed image, viewed through the SEM, of an etching surface of the copper foil used for the multilayer wiring board according to one example of the embodiment of the present invention.

FIG. 11B is an enlarged view of FIG. 11A.

FIG. 12A is an observed image, viewed through the SEM, of an etching surface of the copper foil used for the multilayer wiring board according to one example of the embodiment of the present invention.

FIG. 12B is an enlarged view of FIG. 12A.

FIG. 13A is an observed image, viewed through the SEM, of an etching surface of a commercially available copper foil.

FIG. 13B is a schematic cross sectional view of the commercially available copper foil illustrated in FIG. 13A.

FIG. 14 is a schematic cross sectional view illustrating a connection structure between the copper foil and the via-hole conductor according to the embodiment of the present invention.

FIG. 15A is an observed image, viewed through a laser microscope, of the commercially available copper foil.

FIG. 15B is a diagram illustrating a surface roughness of the commercially available copper foil.

FIG. 16A is an observed image, viewed through a laser microscope, of an etching surface of the copper foil according to the embodiment of the present invention.

FIG. 16B is a diagram illustrating a surface roughness of the copper foil according to the embodiment of the present invention.

FIG. 17A is a diagram illustrating skewness.

FIG. 17B is a diagram illustrating skewness.

FIG. 18A is a cross sectional view illustrating a state in which a fine pattern is formed by etching using a surface-roughened copper foil having skewness of 0 or less.

FIG. 18B is a cross sectional view in a step subsequent to the step illustrated in FIG. 18A.

FIG. 18C is a cross sectional view in a step subsequent to the step illustrated in FIG. 18B.

FIG. 19 is cross sectional view illustrating a state prior to bringing a protruding portion of a via paste into pressure contact with a surface of an electrolytic copper foil which is an etching surface having skewness Rsk of 0 or less of a roughness curve, according to the embodiment of the present invention.

FIG. 20 is a cross sectional view illustrating a state after bringing the protruding portion of the via paste into pressure contact with a surface of the electrolytic copper foil illustrated in FIG. 19.

FIG. 21 is a cross sectional view illustrating a state prior to bringing a protruding portion of a via paste into pressure contact with a surface of a conventional surface-roughened copper foil.

FIG. 22 is a cross sectional view illustrating a state after bringing the protruding portion of the via paste into pressure contact with the surface of the surface-roughened copper foil illustrated in FIG. 21.

FIG. 23A is a schematic cross sectional view of a built-up multilayer wiring board according to the embodiment of the present invention.

FIG. 23B is another schematic cross sectional view of the built-up multilayer wiring board illustrated in FIG. 23A.

FIG. 24A is a cross sectional view illustrating one example of a method for manufacturing the multilayer wiring board illustrated in FIG. 23A.

FIG. 24B is a cross sectional view subsequent to a step illustrated in FIG. 24A, illustrating one example of the method for manufacturing the multilayer wiring

FIG. 24C is a cross sectional view subsequent to a step illustrated in FIG. 24B, illustrating one example of the method for manufacturing the multilayer wiring board.

FIG. 25 is a schematic cross sectional view illustrating a cross section of a via conductor of a conventional multilayer wiring board.

FIG. 26A is a schematic cross sectional view of a conventional surface-roughened foil formed on an insulating layer before etching.

FIG. 26B is a schematic cross sectional view of the surface-roughened foil illustrated in FIG. 26A after etching.

### DESCRIPTION OF EMBODIMENTS

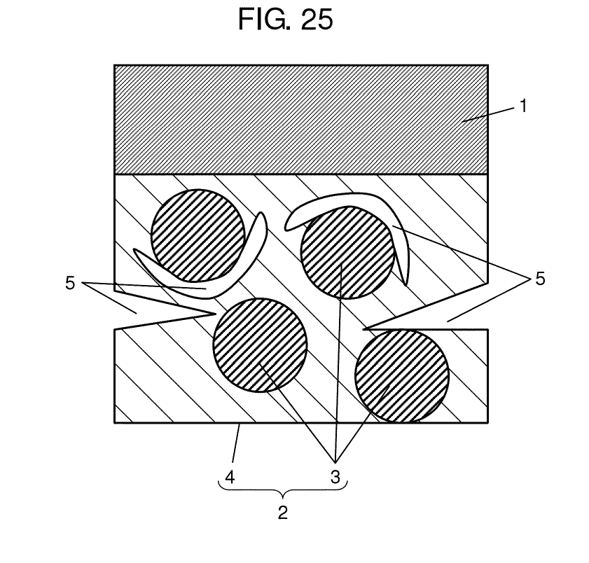

Prior to describing an embodiment of the present invention, a via-hole conductor disclosed in PTL 1 will be described first with reference to FIG. 25 in details as a problem of the conventional technique. FIG. 25 is a schematic cross sectional view of a via-hole portion of a multilayer wiring board disclosed in PTL 1.

Via-hole conductor 2 is in contact with wiring 1 formed on a surface of the multilayer wiring board. Via-hole conductor 2 includes matrix 4 containing intermetallic compounds of Cu₃Sn, and Cu₆Sn₅, and copper particles 3 scattered in matrix 4 as a domain. In via-hole conductor 2, a weight ratio represented by Sn/(Cu+Sn) ranges from 0.25 to 0.75. A matrix-domain structure is formed with such a weight ratio. However, defects 5 such as voids and cracks can be easily formed in via-hole conductor 2 during thermal shock tests.

Defect 5 is caused by formation of a CuSn compound such as Cu₃Sn or Cu₆Sn₅ due to diffusing of Cu into Sn—Bi metal particles when the via-hole conductor 2 is exposed to heat during, for example, thermal shock tests or reflow processing. In addition, Cu₃Sn which is an intermetallic compound of Cu and Sn is included in Cu—Sn diffusion-bonded joints formed at the Cu/Sn interface. The Cu₃Sn changes to Cu₆Sn₅ by heating performed during various reliability tests. It is considered that this change causes an internal stress in via-hole conductor 2 and, as a result, the voids.

Also, a sinterable composition disclosed in PTL 2 is sintered in the presence or absence of a transient liquid phase, which is generated, for example, during hot pressing performed to laminate prepregs. Such a sinterable composition includes Cu, Sn, and Pb. A temperature during hot pressing reaches a high temperature ranging from 180° C. to 325° C. Therefore, it is difficult to apply it to a typical insulating resin layer (glass epoxy resin layer) that is formed by impregnating an epoxy resin in glass fibers. It is also difficult to render it Pb-free as demanded by the market.

Also, in a via-hole conductor material disclosed in PTL 3, an alloy layer formed on a surface layer of the copper particles has high resistance. Therefore, this causes higher resistance as compared with connection resistance obtained only by contact among copper particles or among silver particles as in the case of a typical conductive paste containing the copper particles, the silver particles, or the like.

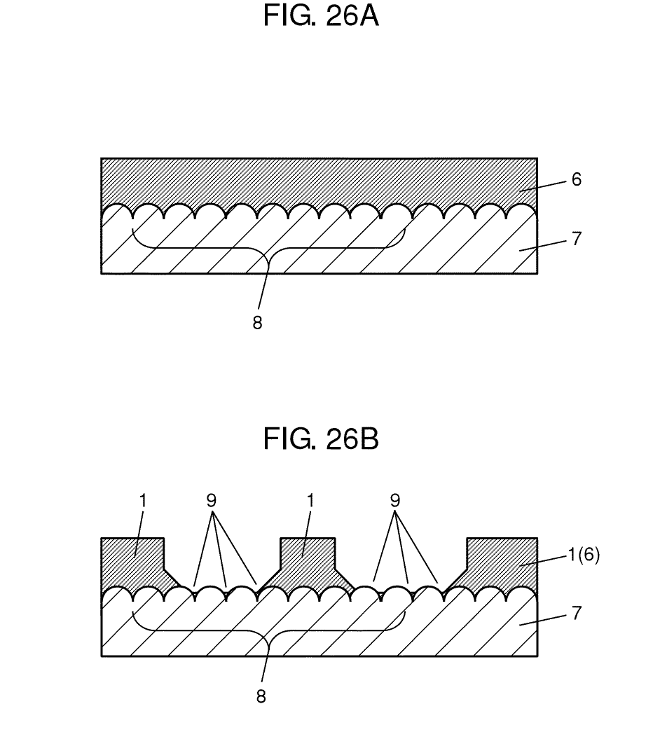

Further, according to a method for manufacturing the laminated circuit board disclosed in PTL 4, when the wiring is finely patterned by an etching method, there is a case where parts of protrusions formed on a surface of a copper foil cannot be removed by etching. With this respect, a description will be given with reference to FIGS. 26A and 26B. FIGS. 26A and 26B are schematic cross sectional views illustrating a problem caused when a conventional surface-roughened foil formed on an insulating layer is subjected to patterning. FIG. 26A illustrates a state before the patterning, and FIG. 26B illustrates a state after the patterning.

As shown in FIG. 26A, conventional surface-roughened foil 6 is fixed with insulating layer 7 in a manner to bring protrusion faces 8 formed by plating or the like into intimate contact with a side of insulating layer 7.

As shown in FIG. 26B, conventional surface-roughed foil 6 is subjected to patterning using a resist or an etchant (both are not illustrated) and formed into wiring 1. Anchor residue 9 means that parts of protruding portions that form protrusion faces 8 formed on the surface of conventional surface-roughened foil 6 bites deeply into insulating layer 7 which is a cured material of a prepreg. The prepreg is formed by, for example, impregnating an epoxy resin into glass fibers, and is on the market. Therefore, even if anchor residue 9 is attempted to be removed, the etchant is difficult to be circulated in the vicinity of anchor residue 9, and therefore it is hard to be etched as compared with a side face of wiring 1. When an etching time is prolonged, etching of the side face of wiring 1 progresses before anchor residue 9 is removed, and this may possibly influence the fine patterning of wiring 1.

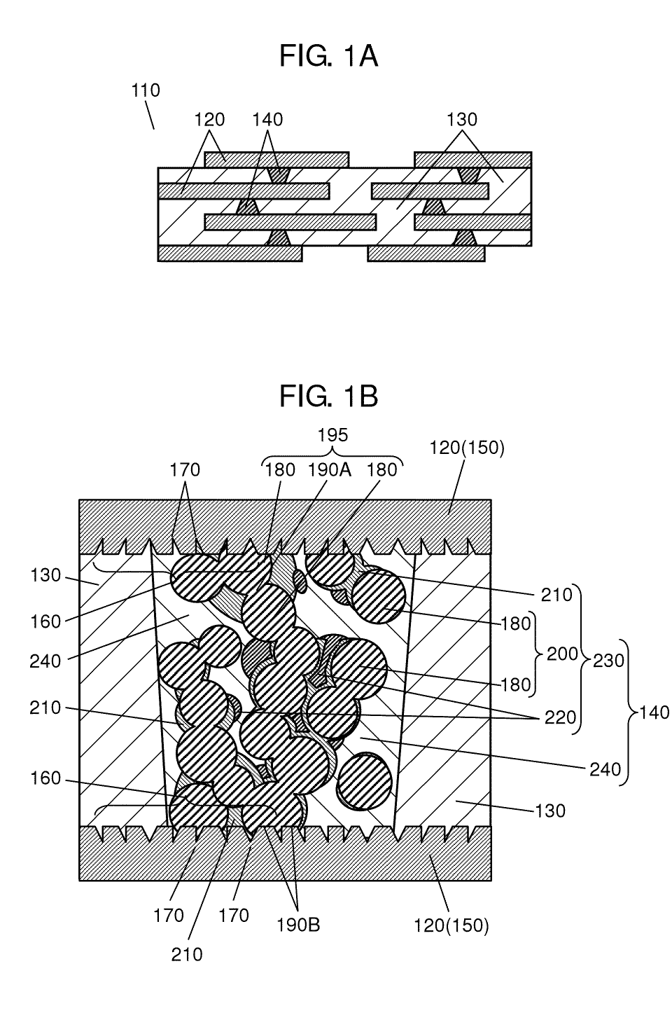

Next, a multilayer wiring board according to an embodiment of the present invention will be described with reference to FIGS. 1A and 1B. FIG. 1A is a schematic cross sectional view of multilayer wiring board 110 according to the embodiment of the present invention. FIG. 1B is an enlarged schematic cross sectional view illustrating via-hole conductor 140 and its vicinity of multilayer wiring board 110 illustrated in FIG. 1A.

As illustrated in FIG. 1A, multilayer wiring board 110 includes wirings 120 formed of a copper foil or the like, insulating resin layer 130, and via-hole conductors 140. Two of wirings 120 sandwich insulating resin layer 130 therebetween. In other words, two wirings 120 oppose to each other with insulating resin layer 130 interposed therebetween. Each of via-hole conductors 140 penetrates through insulating resin layer 130 and is electrically connect two wirings 120 together. Referring to FIG. 1A, wirings 120 are formed three-dimensionally in insulating resin layer 130.

As illustrated in FIG. 1B, via-hole conductor 140 includes metal portion 230 and resin portion 240. Metal portion 230 includes first metal region 200, second metal region 210, and third metal region 220. First metal region 200 is formed of copper particles 180. Second metal region 210 includes, as a main component, at least one type of metal selected from a group consisting of tin, a tin-copper alloy, and a tin-copper intermetallic compound. Third metal region 220 includes Bi as a main component.

In first metal region 200, copper particles 180 are at least partially in contact with and linked to one another via plane-to-plane contact portions 190A where copper particles 180 are in direct plane-to-plane contact with one another. As a result, links 195 of copper particles 180 are formed. Links 195 function as low-resistance conduction paths that electrically connect together wirings 120 that are insulated by insulating resin layer 130.

Wirings 120 are formed by patterning surface-roughened copper foil 150. In other words, a surface of a copper foil on the via-hole conductor 140 side is subjected to etching in advance, and thus roughened to be used as surface-roughened copper foil 150. Groove portions 170 are formed on a surface of surface-roughened copper foil 150 on the via-hole conductor 140 side. More specifically, the surface of surface-roughened copper foil 150 on the via-hole conductor 140 side is etched, and has skewness (Rsk) of 0 or less of roughness curve defined by ISO 4287-1997. Since JIS B0601 corresponds to ISO 4287, skewness Rsk of the roughness curve defined in ISO 4287-1997 may be dealt with as skewness Rsk of a roughness curve defined in JIS B0601-2001. The definition of Rsk and the significance of setting Rsk to 0 or less will be described later.

An average particle size of copper particles 180 is preferably in a range from 0.1 μm to 20 μm, inclusive, and further preferably in a range from 1 μm to 10 μm, inclusive. When the average particle size of copper particles 180 is too small, this tends to cause higher conductive resistance in via-hole conductor 140 due to the increased number of contact points. Also, the particles of such a size tend to be costly. In contrast, when the average particle size of copper particles 180 is too large, there tends to be a difficulty in increasing a filling rate when forming via-hole conductor 140 with a smaller diameter in such a range from 100 μm to 150 μm.

Purity of copper particles 180 is preferably 90 mass % or higher and more preferably 99 mass % or higher. The higher the purity is, the softer copper particles 180 become. Therefore, in a pressurization step that will be described later, copper particles 180 are easily deformed. As a result, when copper particles 180 make contact with one another, copper particles 180 are easily deformed, which increases contact areas among copper particles 180. In addition, this is preferable in the respect that, when the purity is high, a resistance value of copper particles 180 becomes low.

The plane-to-plane contact among copper particles 180 is not a state where copper particles 180 are in contact with each other to the extent of merely touching each other. The plane-to-plane contact is a state where the adjacent copper particles 180 are in contact with each other at their respective planes due to being pressurized and compressed and thus plastically deformed, resulting in increased contact therebetween. In this way, by plastically deforming copper particles 180 which thus adheres to each other, plane-to-plane contact portion 190A therebetween are maintained, even after release of compressive stress. Plane-to-plane contact portions 190A can be checked by observing a sample using a scanning electron microscope (SEM). The sample is created by embedding a formed multilayer wiring board in a resin and then polishing vertical sections of via-hole conductors 140 (using microfabrication such as focused ion beam). Further, the average particle size of copper particles 180 can be measured in a similar manner.

It is assumed that a large amount of analysis cost is incurred to identify a presence of plane-to-plane contact portion 190A among copper particles 180. For this reason, a presence of plane-to-plane contact portion 190A among copper particles 180 can be substantially defined if copper particles 180 are pressed against each other and are deformed, without checking the presence itself.

In addition to formation of plane-to-plane contact portion 190A among copper particles 180, plane-to-plane contact portion 190B is also formed at a contact portion between a rough surface of surface-roughened copper foil 150 (wiring 120) and copper particle 180. As illustrated in FIG. 1B, by forming plane-to-plane contact portion 190B in the contact portion between surface-roughened copper foil 150 and copper particle 180, a connection resistance between surface-roughened copper foil 150 and via-hole conductor 140 can be reduced.

Also, by bringing second metal region 210 and surface-roughened copper foil 150 (wiring 120) into a plane-to-plane contact, a connection strength of an interface therebetween can be increased.

Further, as illustrated in FIG. 1B, at least a part of second metal region 210 is also formed on a surface of surface-roughened copper foil 150 (wiring 120). More specifically, second metal region 210 is formed on the rough surface of surface-roughened copper foil 150 and copper particles 180 so as to straddle plane-to-plane contact portion 190B. With this structure, connection stability between surface-roughened copper foil 150 and via-hole conductor 140 is increased. Specifically, the connection resistance is decreased, and the connection strength is improved.

It is preferable to form groove portions 170 by etching the surface of surface-roughened copper foil 150 (wiring 120). With groove portion 170 being provided, resin portion 240 that is included in via-hole conductor 140 can be accommodated in groove portions 170. As a result, this prevents resin portion 240 from remaining or spreading between surface-roughened copper foil 150 and via-hole conductor 140 when surface-roughened copper foil 150 and via-hole conductor 140 are connected together.

A number of copper particles 180 are brought into plane-to-plane contact with one another to form low-resistance conduction paths between surface-roughened copper foils 150 (wirings 120). In this way, by allowing plane-to-plane contact among a number of copper particles 180, it is possible to reduce connection resistance between surface-roughened copper foils 150.

Also, in via-hole conductors 140, it is preferable that links 195 with a low resistance be formed to have a complicated network, by allowing a number of copper particles 180 to be in random contact with one another as illustrated in FIG. 1B, rather than in orderly arrangement. Formation of such a network by links 195 enables a more reliable electrical connection. It is also preferable that copper particles 180 are in plane-to-plane contact with one another at random positions. By allowing copper particles 180 to be in plane-to-plane contact with one another at the random positions, deformation of the particles enables dispersion of stress caused in via-hole conductors 140 when heat is applied, as well as dispersion of external force applied from outside.

It is preferable that a proportion by weight of copper particles 180 included in via-hole conductor 140 be 20 wt % or more and 90 wt % or less, and further preferably that it be 40 wt % or more and 70 wt % or less. When the proportion by weight of copper particles 180 is too small, a reliability of the electrical connection of links 195 as the conduction paths tends to be reduced. When the proportion by weight of copper particles 180 is too large, the resistance easily fluctuates during reliability tests.

As illustrated in FIG. 1B, at least a part of second metal region 210 is formed in contact with a surface of first metal region 200 excluding plane-to-plane contact portion 190A thereof. In this way, as second metal region 210 is formed on the surface of first metal region 200 excluding plane-to-plane contact portion 190A, first metal region 200 is strengthened. Also, it is preferable that at least a part of second metal region 210 covers a periphery of plane-to-plane contact portion 190A, and covers first metal region 200 so as to straddle plane-to-plane contact portion 190A. With this structure, a contact condition of plane-to-plane contact portion 190A is further enhanced.

Second metal region 210 contains, as a main component, at least one type of metal selected from a group consisting of tin, a tin-copper alloy, and a tin-copper intermetallic compound. Specifically, for example, a metal such as a simple substance of Sn, Cu₆Sn₅, or Cu₃Sn is contained as the main component. Also, for the remainder, other metal elements such as Bi and Cu may be contained to the extent of not harming the effect of the present invention. Specifically, they may be contained in the range of, for example, 10 mass % or less.

Further, as illustrated in FIG. 1B, it is preferable that third metal region 220 be present in contact with second metal region 210 without making contact with copper particles 180. In via-hole conductor 140, in the case where third metal region 220 is disposed so as not to be in contact with copper particles 180, third metal region 220 does not reduce conductivity of first metal region 200. Since resistivity of third metal region 220 containing Bi as a main component is relatively high, it is preferable that a proportion of third metal region 220 be small as much as possible.

Although third metal region 220 contains Bi as the main component, it may contain, as a remainder, an alloy, an intermetallic compound, or the like of Bi and Sn to the extent of not harming the effect of the present invention. Specifically, it may contain such a component, for example in the range of 20 mass % or less.

Since second metal region 210 and third metal region 220 are in contact with each other, they normally contain both Bi and Sn. In this case, second metal region 210 has a higher concentration of Sn than that in third metal region 220, and third metal region 220 has a higher concentration of Bi than that in second metal region 210. It is preferable that an interface between second metal region 210 and third metal region 220 be indefinite rather than definite. When the interface is indefinite, it is possible to prevent stress from concentrating at the interface even under heating conditions for thermal shock tests or the like.

As described above, metal portion 230 that constitutes via-hole conductor 140 contains first metal region 200 formed of copper particles 180; second metal region 210 having, as the main component, at least one type of metal selected from the group consisting of tin, a tin-copper alloy, and a tin-copper intermetallic compound; and third metal region 220 having bismuth (Bi) as the main component.

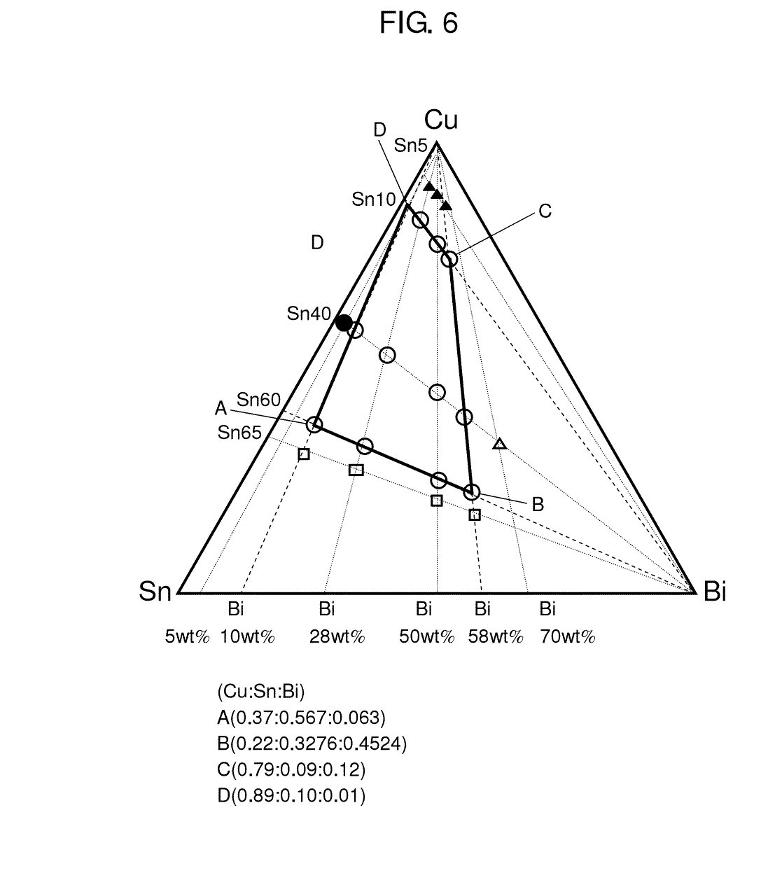

Then, in a ternary plot in FIG. 6 which will be described later, indicating weight ratio of the composition of Cu, Sn, and Bi (Cu:Sn:Bi), a composition of metal portion 230 is in a quadrilateral with vertices of A (0.37:0.567:0.063), B (0.22:0.3276:0.4524), C (0.79:0.09:0.12), and D (0.89:0.10:0.01). When the composition of metal portion 230 is in such a range, via-hole conductor 140 has low resistance and is highly reliable relative to thermal history.

It should be noted that, with respect to the above-mentioned range, in the case where the proportion of Bi relative to Sn is too large, a proportion of third metal region 220 increases when via-hole conductor 140 is formed, resulting in higher resistance. Also, lower connection reliability relative to thermal history is caused according to a manner in which third metal regions 220 are interspersed. In the case where a proportion of Bi relative to Sn is too small, it is necessary to melt the solder component at a high temperature when via-hole conductor 140 is formed. Also, in the case where a proportion of Sn relative to copper particles 180 is too large, copper particles 180 may not sufficiently come into plane-to-plane contact with one another, or a layer of an Sn—Cu compound layer or the like that has high resistance, may be easily formed at the contact plane between copper particles 180. In the case where the proportion of Sn relative to copper particles 180 is too small, metal regions 210 which come into contact with surfaces of links 195 become less, resulting in a lower reliability relative to thermal history.

Meanwhile, resin portions 240 constituting via-hole conductor 140 are made of a cured material of a curable resin. The curable resin is not particularly limited, but, for example, a cured epoxy resin is particularly preferable in terms of excellent heat resistance and a lower coefficient of linear expansion.

A proportion by weight of resin portions 240 in via-hole conductor 140 is preferably 0.1 wt % or more and 50 wt % or less, and more preferably 0.5 wt % or more and 40 wt % or less. When the proportion by weight of resin portions 240 is too large, resistance tends to increase, and when it is too small, preparation of a conductive paste tends to be difficult during manufacturing.

It is preferable that resin portion 240 in via-hole conductor 140 be in a three-dimensional shape with which a gap between first metal region 200 and second metal region 210, and between first metal region 200 or second metal region 210 and third metal region 220 are filled in a matrix shape or a mesh-line shape. A via resistance can be kept low by arranging a shape of resin portion 240 in a three-dimensional net-like structure in this way.

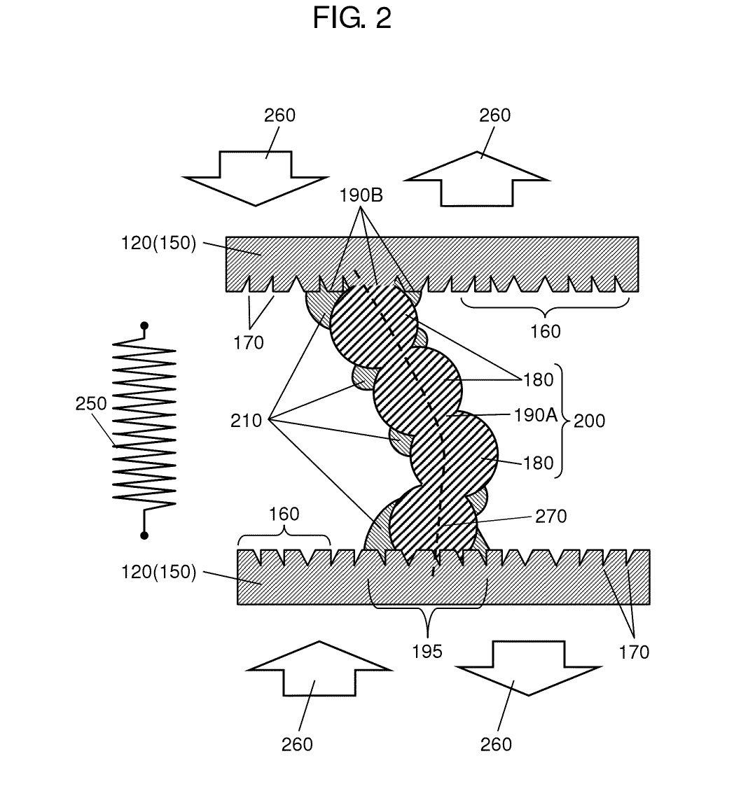

Next, the effect of via-hole conductors 140 in multilayer wiring board 110 will be schematically described with reference to FIG. 2. FIG. 2 is an explanatory drawing for providing a description focusing on a conduction path formed by links 195 each formed by copper particles 180 being in plane-to-plane contact with one another. For convenience sake, resin portions 240 and the like are not illustrated. Furthermore, virtual spring 250 is illustrated for convenience sake for describing the effect of via-hole conductor 140.

As illustrated in FIG. 2, link 195 which is formed by a number of copper particles 180 randomly coming into plane-to-plane contact with one another, forms electric conductive path 270 among a plurality of wirings 120 (surface-roughened copper foils 150). Link 195 is, for example, first metal region 200 formed by copper particles 180 being joined together through plane-to-plane contact portion 190A.

Further, it is effective to form plane-to-plane contact portion 190B between wiring 120 (surface-roughened copper foil 150) and copper particles 180 (first metal region 200). It is also effective that second metal region 210 and wirings 120 (surface-roughened copper foils 150) make plane-to-plane contact with each other. Specifically, it is also effective that second metal region 210 and wirings 120 are integrated together through a metallic compound which is formed by reaction between wiring 120 and solder powder in the via paste.

When internal stress is generated inside multilayer wiring board 110, a force which is outwardly directed as indicated by arrows 260 is applied inside multilayer wiring board 110. Such an internal stress occurs, for example, at the time of solder reflow or thermal shock tests, due to different coefficients of thermal expansion among materials which compose the individual components.

Such an outwardly-directed force is absorbed by deformation of highly flexible copper particles 180 by themselves, elastic deformation of link 195 or first metal region 200, or a slight shift in plane-to-plane contact positions among copper particles 180. Since second metal region 210 is harder than copper particles 180, second metal region 210 resists deformation of link 195, in particular, of plane-to-plane contact portion 190A. Therefore, in the case where plane-to-plane contact portion 190A tends to keep on deforming without limitation, second metal portion 210 regulates the deformation to a certain extent. Therefore, link 195 does not deform to an extent that plane-to-plane contact portion 190A is broken.

When link 195 (or first metal region 200) is likened to a spring, in the case where a force of a certain degree is applied to link 195, the spring is stretched to a certain degree and follows the deformation. However, when the deformation is likely to become greater, the deformation of link 195 is restricted by hard second metal region 210. A similar effect as above is also achieved when a force, which is directed inwardly as indicated by arrows 260, is applied to multilayer wiring board 110. In this way, it is possible to ensure reliability of electrical connection, due to link 195 acting as if it was spring 250 and enabling regulation of deformation of link 195 against forces in any direction, no matter whether it is external or internal.

As described above, via-hole conductor 140 has metal portion 230 and resin portion 240. Metal portion 230 includes copper (Cu), tin (Sn), and bismuth (Bi). Metal portion 230 includes first metal region 200, second metal region 210, and third metal region 220. First metal region 200 includes link 195 of copper particles 180 which electrically connect wirings 120 together. In link 195, copper particles 180 make plane-to-plane contact with one another. Second metal region 210 include, as a main component, at least one of tin, a tin-copper alloy, and a tin-copper intermetallic compound. Third metal region 220 includes Bi as a main component. In this way, although it is useful that copper particles 180 make plane-to-plane contact with one another, this is not restricted to the plane-to-plane contact. It is not necessary to check whether copper particles 180 make plane-to-plane contact with one another, either. There may be a case where a large amount of cost is required to physically check the presence or absence of the plane-to-plane contact of copper particles 180. Therefore, if resistance is low by an electrical assessment, it is possible to assume that copper particles 180 substantial make the plane-to-plane contact with one another, even if individual plane-to-plane contact portions 190A cannot be found. Further, since the plane-to-plane contact of copper particles 180 is caused three-dimensionally, it is not necessary to identify individual plane-to-plane contact portions 190A.

Further, at least a part of second metal region 210 is in contact with a surface of link 195 except surface contact portion 190A thereof. The weight ratio of composition (Cu:Sn:Bi) of Cu, Sn, and Bi in metal portion 230 is in a quadrilateral with vertices of A (0.37:0.567:0.063), B (0.22:0.3276:0.4524), C (0.79:0.09:0.12), and D (0.89:0.10:0.01) in a ternary plot. Wirings 120 are copper foils, and surfaces contacting via-hole conductor 140, of the copper foils are roughened in advance by etching. Second metal region 210 is also formed on the surfaces of the copper foils.

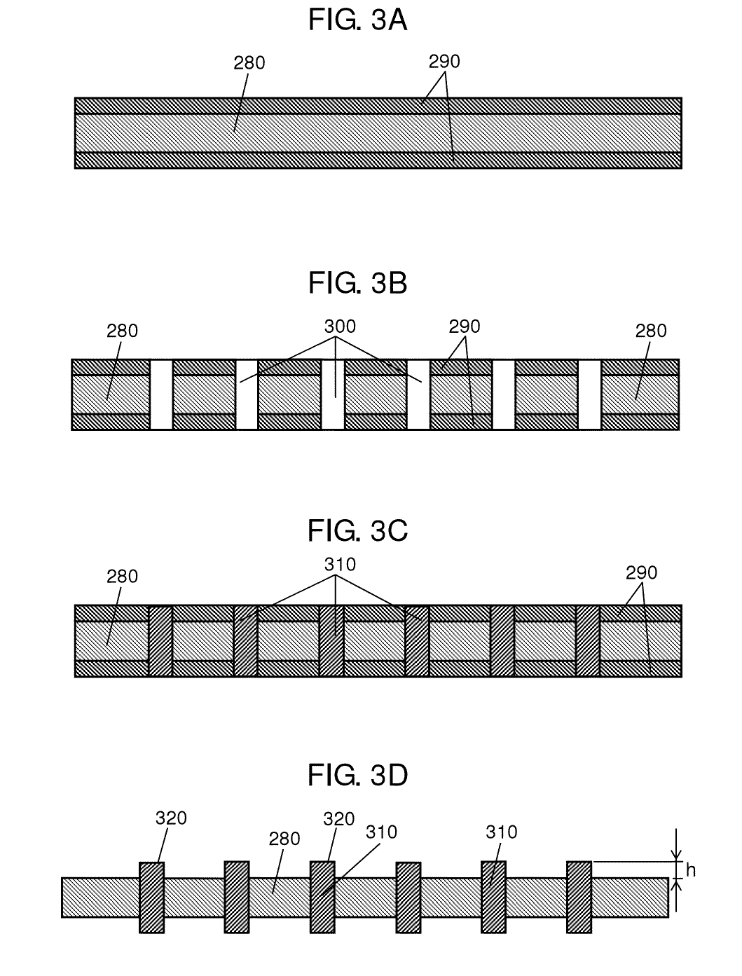

Next, one example of a method for manufacturing multilayer wiring board 110 will be described with reference to FIGS. 3A to 5C. First, as illustrated in FIG. 3A, protective films 290 are attached to both surfaces of prepreg 280. As prepreg 280, for example, a commercially available product with a core material formed of glass fibers or epoxy fibers and impregnated with a semi-cured epoxy resin, or a resin sheet which is a laminate made of a heat-resistant resin sheet with an uncured resin layer laminated on both surfaces thereof can be used, but without particularly limited thereto. In other words, an insulating material that has been conventionally used for manufacturing a wiring board can be used. A heat-resistant resin sheet that is used in manufacturing a wiring board is also one of prepreg 280.

The heat-resistant resin sheet may be any resin sheet that can be used without particular limitation, as long as it withstands a soldering temperature. Specific examples thereof include a polyimide film, a liquid crystal polymer film, and a polyether ether ketone film. It is particularly preferable to use the polyimide film among the foregoing. The heat-resistant resin sheet preferably has a thickness of 1 μm or more and 100 μm or less, more preferably 3 μm or more and 75 μm or less, and particularly preferably 7.5 μm or more and 60 μm or less.

As the uncured resin layer, an adhesive layer that is uncured and made of an epoxy resin or the like can be used. Also, a thickness of the uncured resin layer for each surface of the heat-resistant resin film is preferably 1 μm or more and 30 μm or less, and more preferably 5 μm or more and 10 μm or less, in the respect of contribution to thinning of multilayer wiring board 110.

As protective film 290, various types of resin films are used. Specific examples thereof include resin films of polyethylene terephthalate (PET), polyethylene naphthalate (PEN), and the like. A thickness of the resin film is preferably 0.5 μm or more and 50 μm or less, and more preferably 1 μm or more and 30 μm or less. In the case of this kind of thickness, as described later, it is possible to form a protruding portion of a via paste having a sufficient height, by removing protective film 290.

A method for attaching protective film 290 to prepreg 280 includes a method in which, for example, the film is directly attached to prepreg 280 with use of tackiness of the uncured or semi-cured surface of the uncured resin layer thereof.

Next, as illustrated in FIG. 3B, through-holes 300 are formed by perforating prepreg 280 with protective films 290 disposed thereon, from the outside of protective film 290. For the perforation, various methods such a non-contact processing method using a carbon dioxide gas laser, a YAG laser, or the like, in addition to boring holes using a drill or the like, can be used. A diameter of through-hole 300 is 10 μm or more and 500 μm or less, or about 50 μm or more and 300 μm or less.

Next, as illustrated in FIG. 3C, via paste 310 is fully filled into through-holes 300. Via paste 310 contains copper particles (copper powder), Sn—Bi solder particles (solder powder) containing Sn and Bi, and a curable resin component such as an epoxy resin.

As described previously, the average particle size of the copper particles is preferably in the range from 0.1 μm to 20 μm, inclusive, and more preferably from 1 μm to 10 μm, inclusive. In the case where the average particle size of the copper particles is too small, it is difficult to highly fill through-holes 300, and it also tends to be costly. In contrast, in the case where the average particle size of the copper particles is too large, filling tends to be difficult when via-hole conductors with a smaller diameter are formed.

The copper particles are not particularly limited to any particle shape. Specifically, they may be in a shape such as a spherical, flat, polygonal, scale-like shape, flake-like shape, a shape with protrusions on a surface, or the like. Further, the particles may be primary particles or secondary particles.

Next, as illustrated in FIG. 3D, protective films 290 are removed from surfaces of prepreg 280, thereby allowing via paste 310 to partially protrude from through-holes 300 as protruding portions 320. Height “h” of protruding portion 320 depends on a thickness of protective film 290, but is, for example, preferably 0.5 μm or more and 50 μm or less, and more preferably 1 μm or more and 30 μm or less. When protruding portions 320 are too high, via paste 310 may possibly overflow and spread around through-holes 300 on the surfaces of prepreg 280 during a compression bonding which will be described later, thereby causing loss of surface smoothness. When protruding portions 320 are too low, during the compression bonding which will be described later, pressure does not tend to be sufficiently exerted to via paste 310 that has been filled.

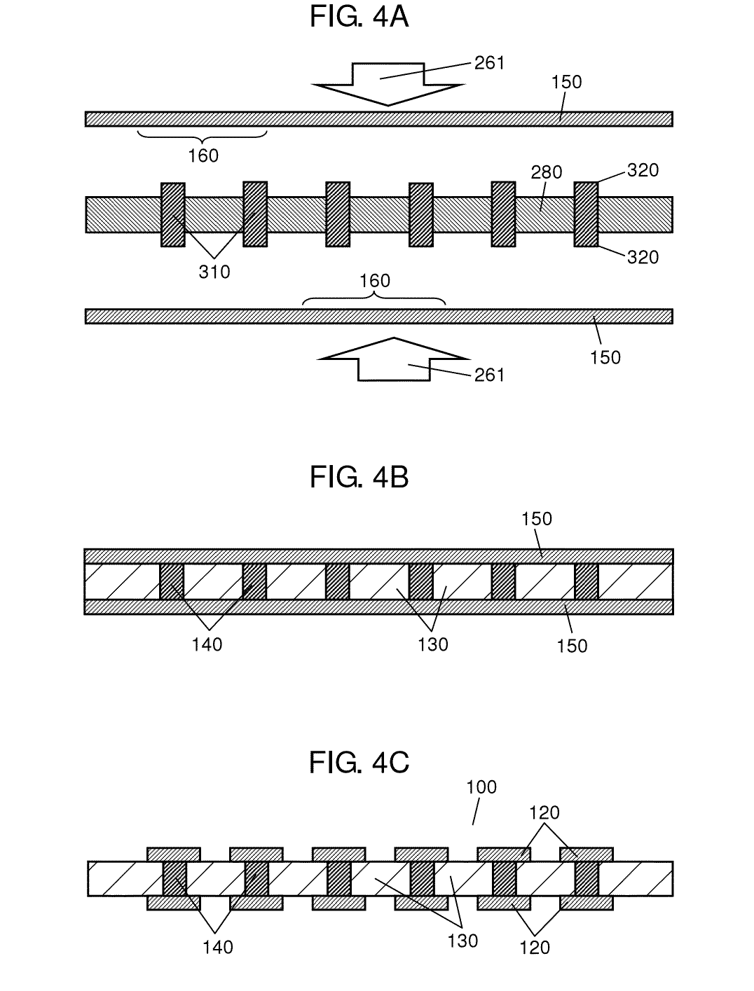

Next, as illustrated in FIG. 4A, surface-roughened copper foils 150 are disposed on both surfaces of prepreg 280 and then pressed in directions indicated by arrows 261. Then, prepreg 280 is integrated with surface-roughened copper foils 150 as illustrated in FIG. 4B. As a result, insulating resin layer 130 is formed. In this case, at the beginning of the pressing, a force is applied to protruding portions 320 through surface-roughened copper foils 150, and therefore via paste 310 that has been filled into through-holes 300 is compressed under a high pressure. Accordingly, a distance between copper particles 180 contained in via paste 310 is decreased, and copper particles 180 are compressed against one another and deformed, allowing them to make plane-to-plane contact.

At this time, as illustrated in FIG. 4A, it is useful to dispose etched surface 160 of surface-roughened copper foil 150 on the via paste 310 side. Pressing conditions are not particularly limited, but the mold temperature is preferably set to be in a range from a room temperature (20° C.) to a temperature lower than a melting point of Sn—Bi solder powder. Also, in this pressing step, to facilitate curing of the uncured resin layer, heating may be applied to bring a temperature to that required for facilitating the curing.

Next, a photoresist film is formed on a surface of each of surface-roughened copper foils 150, and selective exposure through a photomask is performed. Thereafter, an unnecessary portion of the photoresist film is removed by development. Further, the copper foil other than those of the wiring portion is selectively removed by etching. By finally removing the photoresist film, wirings 120 are formed as illustrated in FIG. 4C. A liquid resist or a dry film may be used to form the photoresist film.

In this way, it is possible to form wiring board 100 having circuits formed on both surfaces thereof including upper layer wiring 120 and lower layer wiring 120 that are connected to each other through via-hole conductors 140 serving as an interlayer connection. Further, by multilayering wiring board 100, a multilayer wiring board 110 in which interlayer connections are formed among a plurality of layers of circuits, as illustrated in FIG. 1A, is produced.

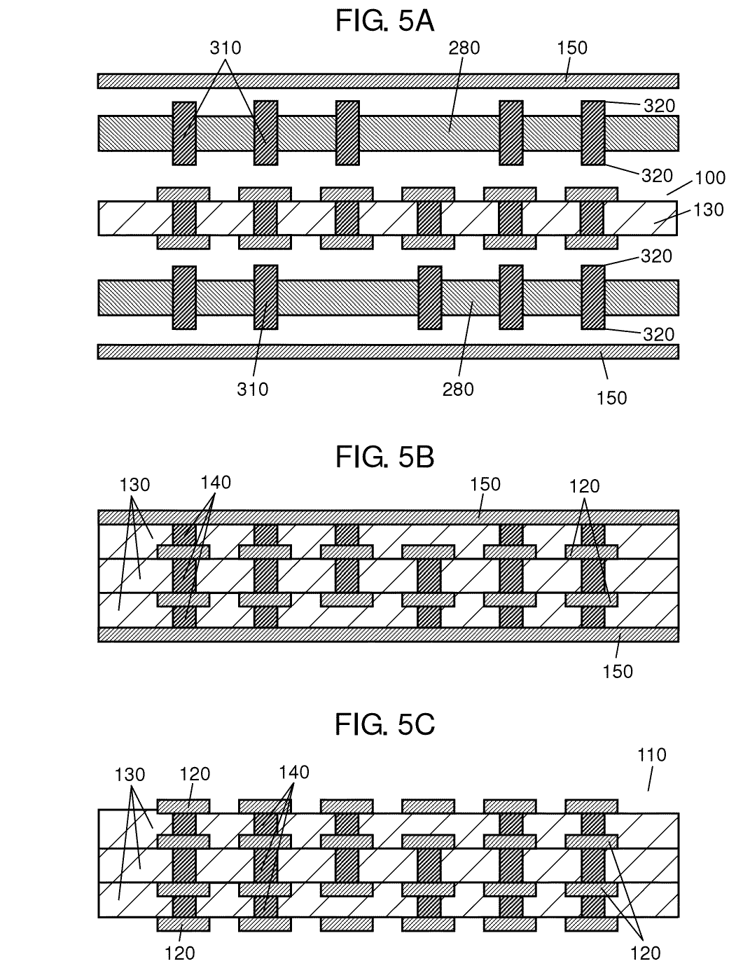

Next, a method for multilayering wiring board 100 will be described with reference to FIGS. 5A to 5C. First, as illustrated in FIG. 5A, prepregs 280 each having protruding portions 320 as illustrated in FIG. 3D are disposed on both surfaces of wiring board 100. Further, surface-roughened copper foils 150 are individually disposed on surfaces each opposite to a surface facing wiring board 100, of prepreg 280 to thereby form a stacked structure. Then, the stacked structure is placed into a mold for pressing, followed by pressing and heating under the conditions as described above. With this operation, a laminate as illustrated in FIG. 5B can be produced. Then, new wirings 120 as illustrated in FIG. 5C are formed by performing the photo processing as described above. By further repeating this multilayering process, multilayer wiring board 110 can be produced. Multilayer wiring board 110 includes three of insulating resin layers 130 and 24 of wirings 120. However, it is a multilayer wiring board if it has two or more of insulating resin layers 130 and three or more of wirings 120.

Next, via paste 310 illustrated in FIGS. 3C to 4A will be described in details with reference to FIG. 6. First, the copper powder and the Si—Bi solder powder will be described with reference to FIG. 6. FIG. 6 is a ternary plot illustrating compositions of Cu, Sn, and Bi of a metallic portion contained in via paste 310.

The Sn—Bi solder powder is a solder powder including Sn and Bi, and the weight ratio of Cu, Sn, and Bi in the paste can be adjusted to come into a quadrilateral with vertices of A, B, C, and D in the ternary plot as illustrated in FIG. 6. The solder powder having such a composition can be used without any particular limitation. Also, the Sn—Bi solder powder may be improved in wettability, flowability, and the like, by adding thereto indium (In), silver (Ag), zinc (Zn), or the like. The Bi content in such Sn—Bi solder powder is preferably 10% or more and 58% or less, and more preferably 20% or more and 58% or less. Furthermore, the Sn—Bi solder powder preferably has a melting point (eutectic point) in a range from 75° C. to 160° C., inclusive, and more preferably in a range from 135° C. to 150° C., inclusive. The Sn—Bi solder powder may be a combination of two or more kinds of particles having different compositions. Particularly preferred among the foregoings is Sn-58Bi solder or the like, which is environmentally-friendly lead-free solder with a low eutectic point of 138° C.

An average particle size of the Sn—Bi solder powder is preferably in a range from 0.1 μm to 20 μm, inclusive, and more preferably 2 μm to 15 μm, inclusive. In the case where the average particle size of the Sn—Bi solder powder is too small, the powder tends to be difficult to melt, due to an increased specific surface area which results in an increased proportion of an oxide film on a surface. In contrast, in the case where the average particle size of the Sn—Bi solder powder is too large, the particles tend to be decreased in filling property into via holes 300.

Specific examples of the epoxy resin, which is a preferable curable resin component, include glycidyl ether epoxy resin, alycyclic epoxy resin, glycidyl amine epoxy resin, glycidyl ester epoxy resin, and other modified epoxy resins.

Also, a curing agent may be combined with the epoxy resin. Although the curing agent is not limited to any particular type, a curing agent containing an amine compound having at least one hydroxyl group in the molecules thereof is particularly preferable. Such a curing agent works as a curing catalyst for the epoxy resin, and also reduces oxide films on a surface of the copper particles and on the surface of the Sn—Bi solder powder. Accordingly, it is desirable in the respect that it reduces the contact resistance when the particles are joined together. Among the foregoing, the amine compound having a boiling point higher than the melting point of the Sn—Bi solder powder is particularly preferable because it has the great effect of reducing contact resistance when the particles are joined together.

Specific examples of such an amine compound include 2-methylaminoethanol (boiling point of 160° C.), N,N-diethylethanolamine (boiling point of 162° C.), N,N-dibutylethanolamine (boiling point of 229° C.), N-methylethanolamine (boiling point of 160° C.), N-methyldiethanolamine (boiling point of 247° C.), N-ethylethanolamine (boiling point of 169° C.), N-butylethanolamine (boiling point of 195° C.), diisopropanolamine (boiling point of 249° C.), N,N-diethylisopropanolamine (boiling point of 125.8° C.), 2,2′-dimethylaminoethanol (boiling point of 135° C.), triethanolamine (boiling point of 208° C.), and the like.

Via paste 310 is prepared by mixing the copper particles, the Sn—Bi solder powder containing Sn and Bi, and the curable resin component such as the epoxy resin. Specifically, via paste 310 is prepared by, for example, adding the copper particles and the Sn—Bi solder powder to a resin varnish which contains an epoxy resin, a curing agent, and a predetermined amount of an organic solvent, and then mixing the resultant with a planetary mixer or the like.

A proportion of the curable resin component to be blended relative to a total amount of the curable resin component and the metal component including the copper particles and Sn—Bi solder powder, is preferably in a range from 0.3 mass % to 30 mass %, inclusive, and more preferably from 3 mass % to 20 mass %, inclusive. This range of blend radio achieves a lower resistance value and ensures sufficient workability.

Also, with respect to the blend ratio between the copper particles and the Sn—Bi solder powder in via paste 310, it is preferable that the respective contents of these particles satisfy the weight ratio of Cu, Sn, and Bi that is in a region enclosed by the quadrilateral of the vertices of A, B, C, and D in the ternary plot as illustrated in FIG. 6. For example, when Sn-58Bi solder powder is used as the Sn—Bi solder powder, the content of the copper particles relative to the total amount of the copper particles and the Sn-58Bi solder powder is preferably 22 mass % or more and 80 mass % or less, and more preferably 40 mass % or more and 80 mass % or less.

The method for filling via paste 310 is not particularly limited. Specifically, for example, a method such as screen printing or the like is used. Meanwhile, it is necessary to adjust an amount of via paste 310 to be filled in through-holes 300 so that protruding portions 320 protrude from a surface when protective films 290 are removed after filling.

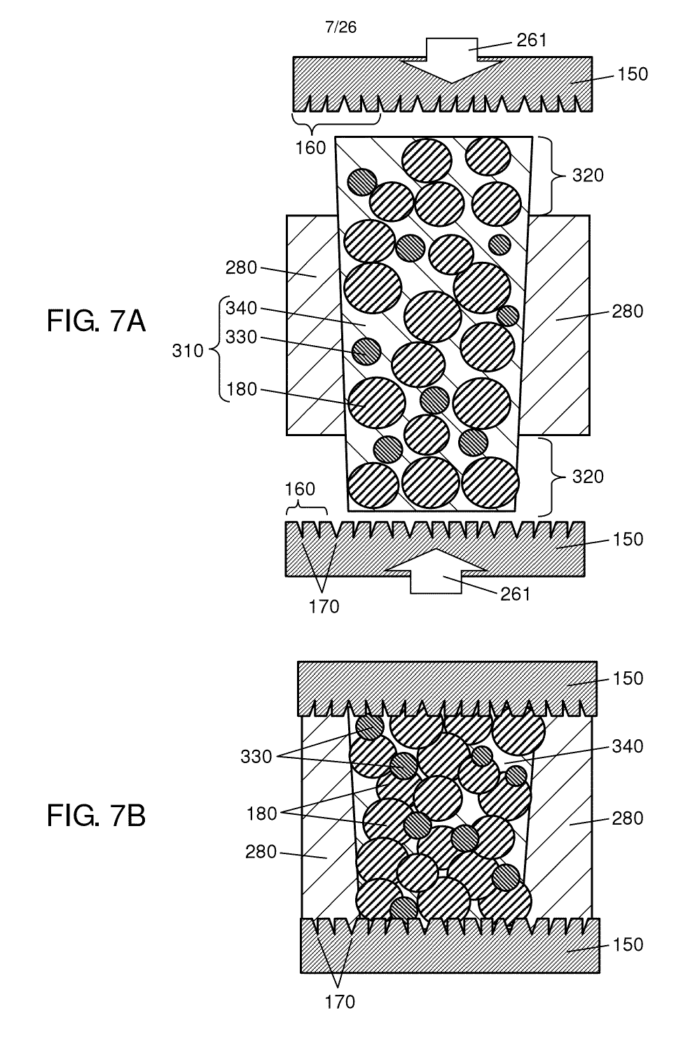

Next, a state in which via paste 310 having protruding portion 320 is compressed as illustrated in FIG. 4A will be described in details with reference to FIGS. 7A and 7B. FIG. 7A is a schematic cross sectional view illustrating a state prior to compression in the vicinity of through-hole 300 of prepreg 280 filled with via paste 310, and FIG. 7B is a schematic cross sectional view illustrating a state after the compression.

Protruding portions 320 protruding from through-hole 300 as illustrated in FIG. 7A are pressed through surface-roughened copper foils 150, so that via paste 310 filled in through-hole 300 is compressed as illustrated in FIG. 7B. At this time, organic component 340 containing the curable resin component may be partially forced out of through-hole 300. As a result, copper particles 180 and Sn—Bi solder particles 330 filled in through-hole 300 increase in density, thereby causing formation of links 195 in which copper particles 180 (or first metal region 200) are in plane-to-plane contact with one another.

Via paste 310 is preferably pressurized and compressed, by compression-bonding surface-roughened copper foil 150 onto prepreg 280, and then applying a predetermined pressure to protruding portions 320 of via paste 310 through surface roughened copper foil 150. This allows copper particles 180 to come into plane-to-plane contact with one another, thereby forming first metal region 200 including links 195 of copper particles 180. To make copper particles 180 come into plane-to-plane contact with one another, it is useful to pressurize and compress copper particles 180 until they are plastically deformed against one another. Also, in this compression bonding, it is useful to perform heating (or start heating) as required. This is because it is useful to perform heating subsequent to the compression bonding.

Further, by directing etched surface 160 of surface-roughened copper foil 150 toward via paste 310, adherence thereof to prepreg 280 is enhanced, and organic component 340 in via paste 310 can be permeated through groove portions 170 or the like formed on etched surface 160. With this arrangement, a degree of contact with surface-roughened copper foil 150, copper particles 180 in via paste 310, and solder particles 330 (further, a degree of plane-to-plane contact by deformation) can be enhanced.

Further, Sn—Bi solder powder is heated at a predetermined temperature to thereby melt a part of Sn—Bi solder powder while the compression bonding state is maintained. In this way, it is possible to prevent molten solder or the like, or resin or the like, from entering plane-to-plane contact portion 190A between copper particles 180. For this reason, it is useful to provide a heating step as a part of the compression bonding step. Also, by starting the heating in the compression bonding step, productivity can be increased since the total time required for the compression bonding step and the heating step can be shortened.

While the compression is maintained, compressed via paste 310 is heated so that Sn—Bi solder particles 330 partially melts at a temperature ranging from the eutectic temperature of Sn—Bi solder particles 330 to the eutectic temperature plus 10° C., inclusive. Subsequently, the resultant is further heated at a temperatures ranging from the eutectic temperature plus 20° C. to 300° C., inclusive. Such two-stage heating is preferable because second metal region 210 can be formed on surfaces of copper particles 180 excluding plane-to-plane contact portion 190A of links 195 of copper particles 180. Further, it is useful to arrange a continuous step including the compression bonding and heating. By this one continuous step, it is possible to stabilize a formation reaction of each of the metal regions, and to stabilize a structure of the vias themselves.

Link 195 (or first metal region 200) is formed by compression, and then via paste 310 is further heated in a gradual manner until a temperature thereof reaches the eutectic temperature of Sn—Bi solder particles 330 or higher and 300° C. or lower. By the heating, solder particles 330 partially melt in an amount equal to that in which the composition can melt at that temperature. Then, second metal regions 210 are formed on surfaces of or in the vicinity of copper particles 180 and links 195 (or first metal region 200). In this case, as described previously, plane-to-plane contact portion 190A, where copper particles 180 are in plane-to-plane contact with one another, is preferably covered and straddled by second metal region 210. As copper particles 180 and molten Sn—Bi solder particles 330 come into contact with each other, Sn in Sn—Bi solder particles 330 and Cu in copper particles 180 react with each other. As a result, second metal regions 210 including, as a main component, a layer of an Sn—Cu compound (intermetallic compound) including Cu₆Sn₅ or Cu₃Sn, or a tin-copper alloy, are formed. On the other hand, solder particles 330 continue to be in a molten state while Sn is compensated from the Sn phase therein, and remaining Bi is deposited. As a result, third metal regions 220 including Bi, as a main component, are formed. These result in formation of via-hole conductors 140 having a structure as illustrated in FIG. 1B.

More specifically, copper particles 180, which are made highly densified as described above, come into contact with one another by the compression. During the compression, copper particles 180 come into point-to-point contact with one another first, and then they are pressed against one another as a pressure is increased. This causes copper particles 180 to deform to thereby come into plane-to-plane contact with one another, resulting in formation of plane-to-plane contact portions 190A. In this way, a number of copper particles 180 come into plane-to-plane contact with one another, which causes formation of links 195 (or first metal region 200) for electrically connecting upper wiring 120 and lower wiring 120 together, with low resistance. Further, plane-to-plane contact portions 190A are not covered with solder particles 330. This means that second metal region 210 does not intrude into plane-to-plane contact portion 190A. Therefore, it is possible to form links 195 in which copper particles 180 are directly in contact with one another. As a result, it is possible to reduce electric resistance of conduction paths 270 illustrated in FIG. 2.

During this state, heating is applied, and solder particles 330 start to partially melt when the temperature reaches the eutectic temperature thereof or higher. The melting composition of the solder is determined by the temperature, and Sn that does not easily melt at the temperature during the heating remains as solid phase substance. Also, when copper particles 180 come into contact with the molten solder, and the surfaces of the particles become wet with the molten Sn—Bi solder, interdiffusion between Cu and Sn progresses at the interface of the wet portion, resulting in formation of an Sn—Cu compound layer or the like. In this way, second metal regions 210 are formed so as to be in contact with the surface of copper particles 180 excluding an area of plane-to-plane contact portion 190A. Second metal region 210 is partially formed so as to straddle plane-to-plane contact portion 190A. In the case where second metal region 210 partially covers plane-to-plane contact portion 190A in a manner to straddle plane-to-plane contact portion 190A, plane-to-plane contact portion 190A is strengthened, and conduction path 270 excellent in elasticity is formed.

Then, with further progression of the formation of the Sn—Cu compound layer or the like, or of the interdiffusion, Sn in the molten solder is decreased. Since this decrease amount of Sn in the molten solder is compensated by the Sn solid phase, the molten state is continued to be maintained. When Sn is further decreased, and the ratio of Bi with respect to Sn becomes greater than that in Sn-57Bi, segregation of Bi begins and solid-phase substances including Bi as a main component are deposited, thereby third metal regions 220 are formed.

Well-known solder materials that melt at relatively low temperatures include Sn—Pb solder, Sn—In solder, Sn—Bi solder, and the like. Among these materials, In is costly, and Pb is highly environmentally unfriendly. On the other hand, the melting point of the Sn—Bi solder is 140° C. or lower, which is lower than a typical solder reflow temperature used when electronic components are surface mounted. Accordingly, in the case where only Sn—Bi solder alone is used for the via-hole conductor of a circuit board, there is a possibility of variation in the via resistance due to remelting of the solder in the via-hole conductor during reflow soldering.

In contrast, with respect to the metallic composition of via paste 310, the weight ratio of the composition of Cu, Sn, and Bi (Cu:Sn:Bi) is in a ternary plot, in a region enclosed by a quadrilateral with vertices of A (0.37:0.567:0.063), B (0.22:0.3276:0.4524), C (0.79:0.09:0.12), and D (0.89:0.10:0.01). In the case where the via paste of such a metallic composition is used, an Sn composition becomes larger as compared with the composition of eutectic Sn—Bi solder (Bi: 57% or less, Sn: 43% or more) in Sn—Bi solder particles 330.

When such via paste 310 is used, part of the solder composition melts at a temperature in a range of the eutectic temperature of solder particles 330 plus 10° C. or lower, while Sn that fails to melt remains. As the Sn concentration in solder particles 330 becomes lower due to diffusion and a reaction of the molten solder at and with the surface of copper particles 180. Therefore, remaining Sn melts. Sn melts also due to a rise in temperature by continued heating, thus resulting in disappearance of Sn in the solder composition which has failed to melt. With the heating further continued and with further progression of the reaction with the surface of copper particles 180. Accordingly, the solid phase substances including Bi as a main component are deposited, thereby third metal regions 220 are formed. In this way, by allowing third metal regions 220 to be deposited and thus be present, the solder in via-hole conductors 140 is hard to remelt even in the reflow soldering. Furthermore, use of solder particles 330 of a Sn—Bi composition with a larger Sn composition enables reduction of the Bi phase remaining in the via. As a result, the resistance can be stabilized and variation in the resistance can be suppressed even after the reflow soldering process.

The temperature for heating via paste 310 after the compression is not particularly limited, as long as it is equal to or higher than the eutectic temperature of the Sn—Bi solder particles 330 and is within a temperature range in which the components of prepreg 280 are not decomposed. Specifically, for example, in the case of using Sn-58Bi solder powder having a eutectic temperature of 139° C. as solder particles 330, it is preferable that the Sn-58Bi solder powder is firstly heated to a temperature in a range from 139° C. to 149° C. to melt a part thereof, and then, the resultant is heated gradually to a temperature in the range from about 159° C. to 230° C. During this process, it is possible to cure the curable resin component included in via paste 310 by selecting the appropriate temperature.

In this way, via-hole conductors 140 as an interlayer connection between upper wiring 120 and lower wiring 120 are formed.

Next, the embodiment will be described in a further specific manner by way of specific examples. It should be noted that the present invention should not be construed as being limited by the following matter.

First, a description of raw materials used in the examples will be given.

Copper particles 180: “1100Y” with an average particle size of 5 μm, available from Mitsui Mining & Smelting Co., Ltd.

Sn—Bi solder particles 330: an alloy powder obtained by blending and melting materials to obtain respective solder compositions indicated in respective compositions shown in Table 1; making the resultant into powder form by atomization; and classifying the resultant so that the average particle size is 5 μm.

Epoxy resin: “jeR871” available from Japan Epoxy Resin K.K.

Curing agent: 2-methylaminoethanol (a boiling point of 160° C.) available from Nippon Nyukazai Co., Ltd.

Prepreg 280: a prepreg having a length of 500 mm, a width of 500 mm and a thickness of 75 μm, made by impregnating glass woven fabrics with a uncured epoxy resin layer.

Protective film 290: a PET sheet with a thickness of 25 μm.

Copper foils: several types of commercially available foils having a thickness in a range from 10 μm to 25 μm, inclusive.

(Preparation of Via Paste)

Metallic components of copper particles 180 and the Sn—Bi solder particles 330 at a blend ratio indicated in Table 1 and resin components of an epoxy resin and a curing agent are blended together, and then mixed with a planetary mixer. In this way, via paste 310 is prepared. The blend ratio of the resin components is 10 parts by weight of the epoxy resin and 2 parts by weight of the curing agent relative to a total of 100 parts by weight of the metallic components.

(Production of Multilayer Wiring Board)

Protective films 290 are attached to both surfaces of prepreg 280. Then, 100 or more through-holes 300 having a diameter of 150 μm are formed from the outer side of prepreg 280 to which protective films 290 are attached, by using a laser.

Next, via paste 310 is fully filled into through-holes 300. Then, protective films 290 are removed, thereby forming protruding portions 320 in which via paste 310 partially protrudes from through-holes 300.

Next, surface-roughened copper foils 150 are disposed on both surfaces of prepreg 280 so as to cover protruding portions 320. Then, a laminate of surface-roughed copper foil 150 and prepreg 280 is placed on a lower mold (not illustrated) of molds for heat pressing through exfoliate paper (not illustrated), and heat pressing is performed between the lower mold and an upper mold (not illustrated). During this process, the lower mold and the upper mold are heated in 60 minutes from a normal temperature of 25° C. to a maximum temperature of 220° C., kept at the temperature of 220° C. for 60 minutes, and cooled down to the normal temperature in 60 minutes. A pressure for the pressing is 3 MPa. In this way, multilayer wiring board 100 is produced.

TABLE 1

| | Metallic composition | | | | | | | | | |
|---|---|---|---|---|---|---|---|---|---|---|
| | | | Copper | | | | | | | |
| | Weight ratio of | Solder | powder | Solder | Initial | Maximum | Evaluation | | | |
| | composition | composition | amount | amount | resistance | resistance | Initial | Maximum | Connection | Plot in |
| Sample | Cu:Sn:Bi | Sn:Bi | (wt %) | (wt %) | (mΩ) | (mΩ) | resistance | resistance | reliability | FIG. 6 |
| C1 | 0.59:0.3895:0.0205 | 1:5 | 59 | 41 | 1.01 | 1.25 | A | A | B | |
| E1 | 0.57:0.387:0.043 | 1:10 | 57 | 43 | 1.30 | 1.42 | A | A | A | ◯ |
| E2 | 0.37:0.567:0.063 | 1:10 | 37 | 63 | 1.80 | 1.99 | A | A | A | ◯ |
| C2 | 0.33:0.603:0.067 | 1:28 | 33 | 67 | 2.10 | 2.51 | B | A | A | □ |
| C3 | 0.93:0.0504:0.0196 | 1:28 | 93 | 7 | 0.91 | 1.80 | A | A | B | ▴ |
| E3 | 0.87:0.0936:0.0364 | 1:28 | 87 | 13 | 0.99 | 1.10 | A | A | A | ◯ |
| E4 | 0.52:0.3456:0.1344 | 1:28 | 52 | 48 | 1.50 | 1.80 | A | A | A | ◯ |
| E5 | 0.32:0.4896:0.1904 | 1:28 | 32 | 68 | 1.90 | 2.10 | A | A | A | ◯ |
| C4 | 0.28:0.5184:0.2016 | 1:28 | 28 | 72 | 2.20 | 2.50 | B | A | A | □ |
| C5 | 0.9:0.05:0.05 | 1:50 | 90 | 10 | 0.92 | 1.30 | A | A | B | ▴ |
| E6 | 0.82:0.09:0.09 | 1:50 | 82 | 18 | 0.94 | 1.10 | A | A | A | ◯ |
| E7 | 0.43:0.285:0.285 | 1:50 | 43 | 57 | 1.80 | 2.20 | A | A | A | ◯ |
| E8 | 0.25:0.375:0.375 | 1:50 | 25 | 75 | 2.00 | 2.80 | A | A | A | ◯ |
| C6 | 0.21:0.395:0.395 | 1:50 | 21 | 79 | 2.50 | 3.10 | B | B | A | □ |
| C7 | 0.73:0.081:0.189 | 1:70 | 73 | 27 | 1.21 | 1.60 | A | A | B | Δ |
| C8 | 0.89:0.462:0.0638 | 1:58 | 89 | 11 | 0.94 | 1.28 | A | A | B | ▴ |
| E9 | 0.79:0.0882:0.1218 | 1:58 | 79 | 21 | 1.19 | 1.59 | A | A | A | ◯ |
| E10 | 0.60:0.168:0.232 | 1:58 | 60 | 40 | 1.28 | 1.67 | A | A | A | ◯ |
| E11 | 0.39:0.2562:0.3538 | 1:58 | 39 | 61 | 1.80 | 2.10 | A | A | A | ◯ |
| E12 | 0.22:0.3276:0.4524 | 1:58 | 22 | 78 | 1.90 | 2.50 | A | A | A | ◯ |
| C9 | 0.18:0.3444:0.4756 | 1:58 | 18 | 82 | 2.10 | 3.10 | B | B | A | □ |

(Resistance Test)

The 100 pieces of via-hole conductors 140 formed in wiring board 100 which is produced as described above are measured for resistance by a four-terminal method. Then, an average value for the 100 pieces is set as an initial resistance, and maximum resistance is obtained from the 100 pieces. Here, a sample having the initial value of 2 MΩ or less is evaluated as “A”, and a sample having the initial value larger than 2 MΩ is evaluated as “B”. Further, a sample having the maximum resistance less than 3 MΩ is evaluated as sample “A”, and a sample having the maximum resistance larger than 3 MΩ is evaluated as “B”.

(Connection Reliability)

After measuring the initial resistance, multilayer wiring board 100 measured is subjected to a thermal cycle test of 500 cycles. A sample whose change rate of resistance with respect to the initial value is 10% or less is evaluated as “A”, and a sample whose change rate is larger than 10% is evaluated as “B”.

Results are shown in Table 1. Also, FIG. 6 shows a ternary plot depicting respective compositions of the examples indicated in Table 1. In FIG. 6, white circles depict respective compositions of examples E1 to E12, and a black solid circle depicts a composition of example C1 in which an amount of Bi relative to an amount of Sn is smaller as compared with samples E1 to E12. A white triangle depicts a composition of sample C7 in which an amount of Bi relative to an amount of Sn is larger as compared with samples E1 to E12; squares depict the respective compositions of samples C2, C4, C6, and C9 in which an amount of Sn relative to an amount of Cu is larger as compared with samples E1 to E12. Further, black solid triangles depict respective compositions of samples C3, C5, and C8 in which an amount of Sn relative to an amount of Cu is smaller as compared with samples E1 to E12.

From FIG. 6, it is understood that the weight ratios (Cu:Sn:Bi) in the ternary plot of respective compositions of examples E1 to E12 evaluated as “A” in every category of the initial resistance, the maximum resistance, and the connection reliability are in the region (including a border) enclosed by a quadrilateral with vertices of A (0.37:0.567:0.063), B (0.22:0.3276:0.4524), C (0.79:0.09:0.12), and D (0.89:0.10:0.01).

Also, example C7 indicated by the white triangle in FIG. 6 has a larger amount of Bi deposited in the vias. A conductive resistance of Bi is 78 μΩ·cm, and is remarkably greater than those of Cu (1.69 μΩ·cm), Sn (12.8 μΩ·cm), and a Cu—Sn compound (Cu₃Sn:17.5 μΩ·cm, Cu₆Sn₅:8.9 μΩ·cm). Therefore, the resistance cannot be sufficiently lowered when the amount of Bi relative to the amount of Sn is large, and the connection reliability is reduced, since resistance changes according to an interspersed state of Bi.

Also, samples C2, C4, C6, and C9, which are indicated by the squares in FIG. 6, cause insufficient formation of plane-to-plane contact portion 190A among copper particles 180, or formation of an Sn—Cu compound layer at the contact portions among copper particles 180 after interdiffusion. For this reason, they have larger initial resistance and maximum resistance.

Also, according to sample C1 indicated by the black solid circle in FIG. 6, an amount of solder, which melts at a temperature of about 140° C. which is a eutectic temperature of the Sn—Bi solder powder, is small due to a small amount of Bi. For this reason, the Sn—Cu compound layer (second metal region 210) for reinforcing plane-to-plane contact portion 190A is not sufficiently formed, which reduces the connection reliability. That is, in the case of sample C1 using the Sn-5Bi solder powder, the initial resistance and the maximum resistance are smaller due to formation of plane-to-plane contact portion 190A. However, it is presumed that solder particles 330 are made difficult to melt due to a small amount of Bi, and a reaction between Cu and Sn for forming the Sn—Cu compound layer, which reinforces plane-to-plane contact portion 190A, does not sufficiently progress.

Further, according to samples C3, C5, and C8 which are indicated by the black solid triangles in FIG. 6, since an amount of Sn relative to copper particles 180 is small, the Sn—Cu compound layer, which reinforces plane-to-plane contact portion 190A, is reduced. For this reason, the connection reliability is reduced.

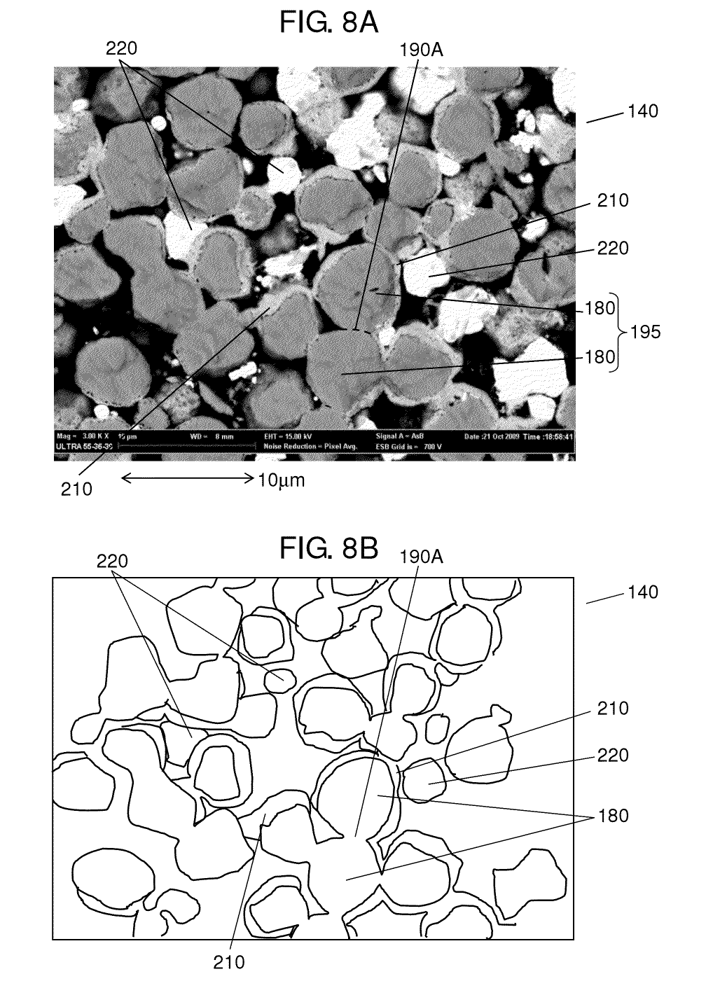

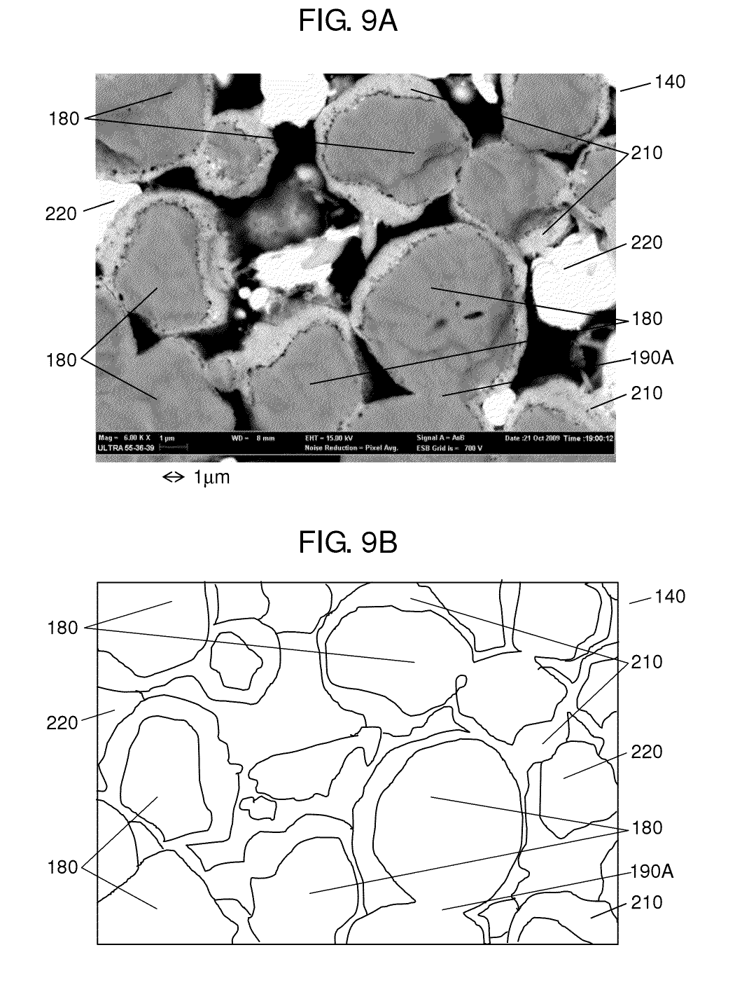

Here, as typical examples, FIGS. 8A to 9B show photograph images, viewed through an electron microscope (SEM), of a cross section of via-hole conductor 140 of wiring board 100 which is produced using a via paste according to sample E10, and a schematic diagram thereof. A magnification used for FIG. 8A is 3000 times, and a magnification used for FIG. 9A is 6000 times. FIGS. 8B and 9B are traced drawings of FIGS. 8A and 9A, respectively.

From these images and drawings, it is understood that a number of copper particles 180 are densely filled and come into plane-to-plane contact with one another, thereby forming plane-to-plane contact portions 190A in via-hole conductor 140. From this, conduction paths with low resistance are formed. Also, second metal region 210 is formed so as to straddle plane-to-plane contact portion 190A, on surfaces of links 195 each formed by copper particles 180 coming into plane-to-plane contact with one another. Also, third metal regions 220 including, as a main component, Bi having high resistance are substantially not in contact with copper particles 180. It is presumed that third metal regions 220 is formed as a resultant of deposited Bi at high concentrations due to Sn forming an alloy (e.g., intermetallic compound) with Cu on surfaces of copper particles 180.

Next, with respect to samples E13 to E15, a description will be given of a result of studies made on effects of the curing agent depending on a kind thereof. Specifically, wiring boards 100 are produced in the same manner as samples E1 to E10 by using Sn-58Bi particles as Sn—Bi solder particles 330 and setting weight ratio of the copper particles and the solder powder (solder particles 330) in the metallic component to 56% and 44%, respectively, and wiring boards 100 are evaluated. Table 2 indicates types of the curing agents. Note that further fine classification is made for the connection reliability. Specifically, samples whose change rate of resistance with respect to the initial value is 1% or more and 5% or less are evaluated as “S”, 5% or more and 10% or less are evaluated as “A”, and more than 10% are evaluated as “B”. Table 2 indicates the result. Further, a weight ratio of a composition of Cu:Sn:Bi is 0.56:0.1848:0.2552.

TABLE 2

| | | Initial | Maximum | Evaluation | | |
|---|---|---|---|---|---|---|
| | | resistance | resistance | Initial | Maximum | Connection |
| Sample | Curing agent | (mΩ) | (mΩ) | resistance | resistance | reliability |
| E13 | 2-methylaminoethanol, | 2.00 | 2.00 | A | A | S |
| | boiling point of 160° C. | | | | | |
| E14 | 2-diisopropanolamine, | 2.00 | 2.00 | A | A | S |
| | boiling point of 250° C. | | | | | |
| E15 | 2,2-dimethylaminoethanol, | 2.00 | 2.00 | A | A | A |
| | boiling point of 135° C. | | | | | |

In samples E13 and E14, curing agents each having a boiling point of 139° C. or more, which is the eutectic temperature of the Sn-58Bi solder are used. From the result indicated in Table 2, wiring boards 100 according to samples E13 and E14 have a remarkably low change rate with respect to the initial resistance in a connection reliability test and are excellent in the connection reliability. In the case where the boiling point of the curing agent is higher than the eutectic temperature of the Sn—Bi solder, reduction of an oxide layer present on a surface of the Sn—Bi solder does not progress, and therefor volatilization of the curing agent does not occur before the solder melts. It is presumed that second metal regions 210 are sufficiently formed, thus improving the reliability thereof for this reason. It is preferable that the boiling point of the curing agent be 300° C. or lower. If it is higher than 300° C., the curing agent is atypical, which may affect its reactivity.

Next, various types of copper foils (plain foil which is a commercially available copper foil, a conventional surface-roughened copper foil which is a commercially available surface-roughened copper foil, and the surface-roughened copper foil according to this embodiment) are subjected to patterning as illustrated in FIG. 4C, and one example of evaluation on presence or absence of the anchor residue is shown in Table 3.

Similar results are obtained from the respective copper foils having a thickness of 10 μm or more and 30 μm or less. Referring to JIS Standards, maximum height Rz (unit thereof is μm) which is an index of surface roughness represents a height difference between a highest crest and a lowest trough of a roughness curve excluding undulation of a surface thereof. Further, the evaluation of patterning is made for each of cases where L/S (Line/Space, i.e., line width/line spacing) is 50 μm/50 μm, 30 μm/30 μm, and 20 μm/20 μm.

In Table 3, “None” represents a case where the “anchor residue” is caused only below a range in which the “anchor residue” does not cause any quality problem. “Peeling present” represents a case where the evaluation of the presence or absence of the “anchor residue” cannot be made due to an occurrence of “pattern peeling”. “Anchor residue presence” represents a case where, although the “pattern peeling” is not caused, but the “anchor residue” is caused, which may cause a quality problem.

As indicated in Table 3, in the cases where L/S is 30 μm/30 μm and 20 μm/20 μm, the plain foil causes the “pattern peeling”, and the presence or absence of the “anchor residue” cannot be evaluated. Rz of the plain foil ranges from 0.1 μm to 0.3 μm, the surface roughness is small, an anchor effect is thus small because adhesion between insulating resin layer 130 and the copper foil is small, therefore, formation of pattern is difficult, and insulating resin layer 130 is peeled off.

Further, according to the conventional surface-roughened foil (commercially available surface-roughened copper foil), the “anchor residue” is caused in the cases where L/S is 30 μm/30 μm and 20 μm/20 μm. Rz of the conventional surface-roughened foil ranges from 5.0 μm to 12 μm, the surface roughness is large, an anchor effect is thus large because adhesion between insulating resin layer 130 and the copper foil is large. Therefore, anchor residue 9 tends to be caused as illustrated in FIG. 26B previously mentioned.

In contrast, in the case of the surface-roughened copper foil (surface-roughened copper foil 150 according to this embodiment), neither the “anchor residue” nor the “pattern peeling” are caused in any of the cases where L/S is 50 μm/50 μm, 30 μm/30 μm, and 20 μm/20 μm.

TABLE 3

| | | L/S = | L/S = | L/S = |
|---|---|---|---|---|
| Copper foil | Rz (μm) | 50/50 | 30/30 | 20/20 |
| Plain foil | 0.1-0.3 | None | Peeling | Peeling |
| | | | present | present |
| Conventional | 5.0-12 | None | Anchor | Anchor |
| surface- | | | residue | residue |
| roughened foil | | | present | present |
| Surface- | 0.2-2.0 | None | None | None |
| roughened | | | | |
| copper foil | | | | |

Next, each copper foil is subjected to patterning as illustrated in FIG. 4C, and one example of evaluation on the pattern peeling is shown in Table 4.

TABLE 4

| | | | | | Peel |
|---|---|---|---|---|---|
| | | L/S = | L/S = | L/S = | strength |
| Copper foil | Rz (μm) | 50/50 | 30/30 | 20/20 | (kN/m) |
| Plain foil | 0.1-0.3 | Partially | Present | Present | 0.1-0.3 |
| | | present | | | |
| Conventional | 5.0-12 | None | None | None | 1.0-1.2 |
| surface- | | | | | |
| roughened foil | | | | | |
| Surface- | 0.2-2.0 | None | None | Partially | 0.7-0.9 |
| roughened | | | | present | |
| copper foil | | | | | |

In Table 4, “None” represents a case where the “pattern peeling” is only caused below a range in which the “pattern peeling” causes no quality problem. “Partially present” represents a case where the “pattern peeling” is partially caused in a narrow range and presents a quality problem. “Present” represents a case where the “pattern peeling” is caused in a wide range and presents a quality problem. Table 4 also indicates a peel strength.

As indicated in Table 4, Rz of the plain foil is in a range from about 0.1 μm to 0.3 μm, the surface roughness is small, and adhesion between insulating resin layer 130 and the copper foil is small. As a result, the peel strength is small such as from 0.1 kN/m to 0.3 kN/m. For this reason, according to the plain foil, although the “pattern peeling” is “partially present” in the case where L/S is 50 μm/50 μm, the “pattern peeling” is further enlarged in the cases where L/S is 30 μm/30 μm, and 20 μm/20 μm. In this way, the pattern peeling tends to be easily caused.

According to the conventional surface-roughened foil, Rz thereof ranges from 5.0 μm to 12 μm, the surface roughness is large, and the adhesion between insulating resin layer 130 and the copper foil is large. Therefore, the peel strength thereof is large such as ranging from 1.0 kN/m to 1.2 kN/m. Accordingly, the pattern peeling is not caused even in the cases where L/S is 30 μm/30 μm, and 20 μm/20 μm.

According to the surface-roughened copper foil, although the “pattern peeling” is “none” in the case where L/S is 30 μm/30 μm, the “pattern peeling” is “partially” caused in the case where L/S is 20 μm/20 μm. However, according to the surface-roughened copper foil, since the peel strength is relatively high such as ranging from 0.7 kN/m to 0.9 kN/m, there is a possibility of reducing the “pattern peeling” by changing an etching condition such as reducing a spraying pressure during spraying an etchant.

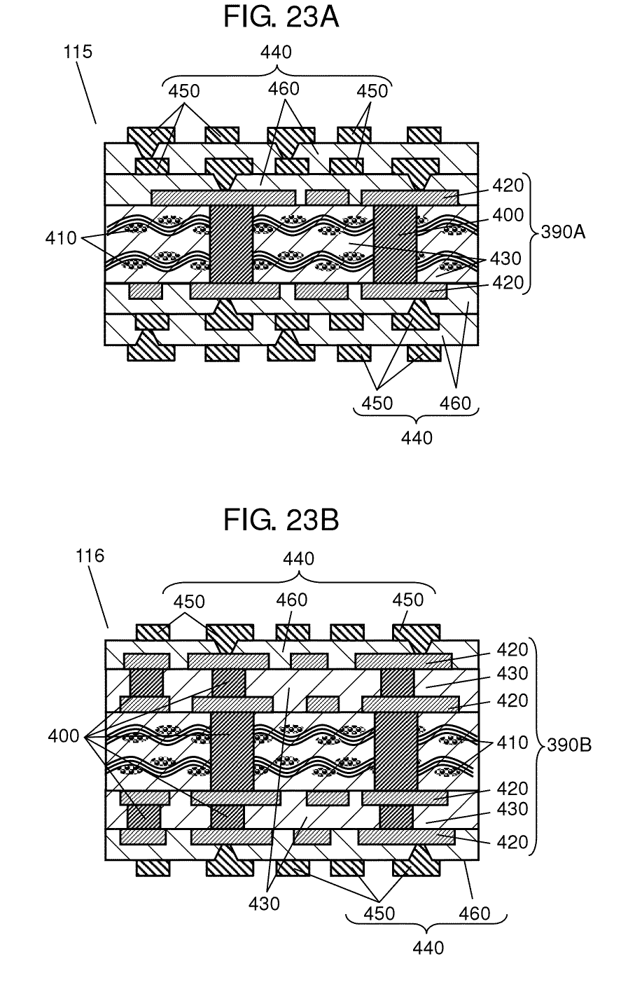

Meanwhile, in the case where wiring is densely formed in multilayer wiring board 110 illustrated in FIG. 5C and a built-up multilayer wiring board illustrated in FIG. 23A as discussed later, it is necessary to reduce a diameter of the via, and further reduce a diameter of the via land portion, in addition to fine patterning of the wiring. Specifically, it is preferable to make the diameter of via-hole conductor 140 to 10 μm or larger and 100 μm or smaller. It may be difficult to fill via paste 310 into via-hole 300 having a diameter smaller than 10 μm. In addition, when a diameter of via-hole conductor 140 exceeds 100 μm, it may adversely affect high densification of multilayer wiring board 110. Further, the built-up multilayer wiring board includes a core substrate portion, and a built-up layer formed by a built-up method on the core substrate portion. It is demanded to make a diameter of the via smaller, for example, to 150 μm and finally to 30 μm.

However, as the via diameter becomes smaller, the via resistance increases more. Therefore, to reduce the via resistance of a via having a smaller diameter, it is useful to further reduce connection resistance (or contact resistance) between wiring 120 and via-hole conductor 140 in addition to reducing volume resistance of via-hole conductor 140. Particularly, to reduce the via diameter (diameter of via-hole conductor 140) to 100 μm or less, it is useful to reduce connection resistance by deforming both surface-roughened copper foil 150 having low resistance and copper particles 180 to thereby form plane-to-plane contact portion 190B. In addition, it is useful to improve strength by forming an alloy between solder particles 330 and surface-roughened copper foil 150 directly on a surface of surface-roughened copper foil 150, and forming second metal region 210 that partially forms via-hole conductor 140. In this case, it is preferable that at least a part of second metal region 210 covers a periphery of plane-to-plane contact portion 190B, and covers surface-roughened copper foil 150 and copper particles 180 in a manner to straddle plane-to-plane contact portion 190B.

As described above, it is possible to increase the connection strength of surface-roughened copper foil 150 with first metal region 200 by directly forming second metal region 210 on the surface of surface-roughened copper foil 150, and electrical characteristics and reliability can be increased even in the case where the via diameter is reduced to 100 μm or smaller. Here, the via diameter is smaller than a width of wiring 120. Therefore, the via diameter can be larger than 0 μm.

Further, as described later, it is also useful to arrange wiring board 100 illustrated in FIG. 4C or multilayer wiring board 110 illustrated in FIG. 5C as a core substrate, form a built-up layer portion on the core substrate using commercially available built-up materials to form a built-up multilayer wiring board. According to wiring board 100, it is easy to reduce the via diameter thereof, and perform fine patterning of wiring 120. Wiring board 100 is excellent in low resistance, and high reliability (or highly strengthened) even after wiring 120 is finely patterned. For this reason, wiring board 100 and multilayer wiring board 110 satisfy the requirements required for a core substrate.

As described above, multilayer wiring board 110 according to this embodiment can cope with further fine patterning (e.g., L/S is 20 μm/20 μm or larger and 50 μm/50 μm or smaller). Note here that it is not necessary to provide the fine pattern on an entire surface of multilayer wiring board 110. A fine pattern with L (Line width) which is 20 μm or larger and 50 μm or smaller may be partially provided to multilayer wiring board 110. With this arrangement, the freedom of pattern design of multilayer wiring board 110 can be enhanced. Similarly, the freedom of pattern design of multilayer wiring board 110 can be enhanced by partially providing a fine pattern with S (width Spacing) which is 20 μm or larger and 50 μm or smaller in part of multilayer wiring board 110.

A thickness of surface-roughened copper foil 150 is preferably 5 μm or more and 50 μm or less, and more preferably 10 μm or more and 30 μm or less. In the case where the thickness of surface-roughened copper foil 150 is less than 5 μm, wiring resistance may be increased when the fine patterning is applied. Also, in the case where the thickness of surface-roughened copper foil 150 exceeds 50 μm, the fine patterning may become difficult.

It is understood from the results indicated in Table 3 and Table 4 that the surface-roughened copper foil (surface-roughened copper foil 150) provides a most outstanding result. In addition, since this can be applied to fine patterning of L/S, it is possible to make a diameter of the land portion of the via portion smaller, and arrange the vias in a high-density manner.

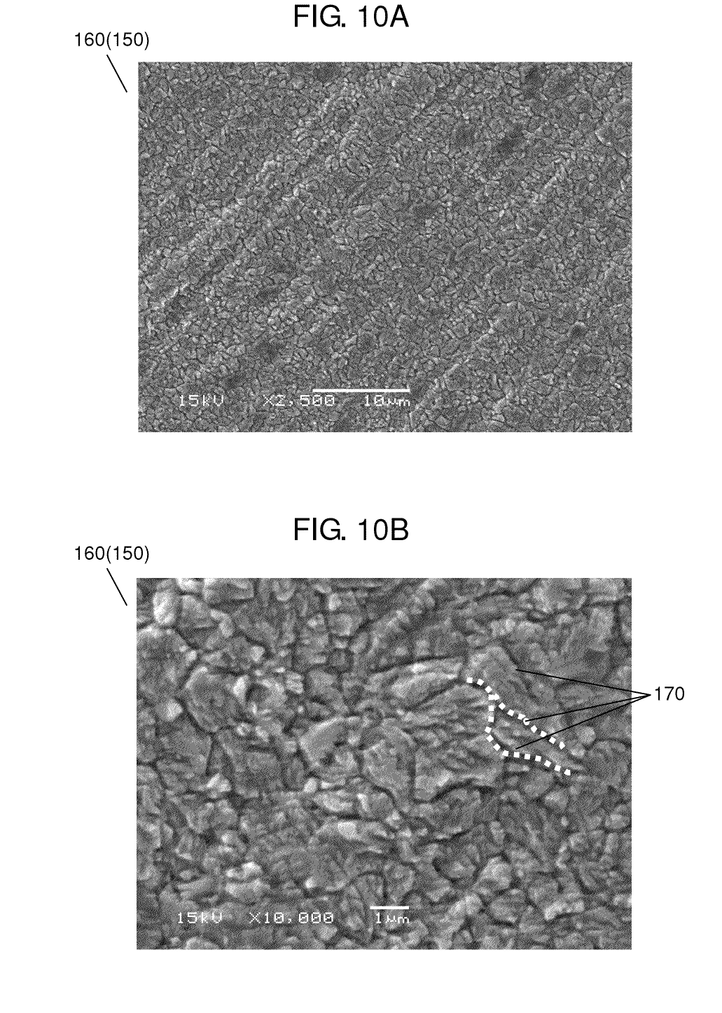

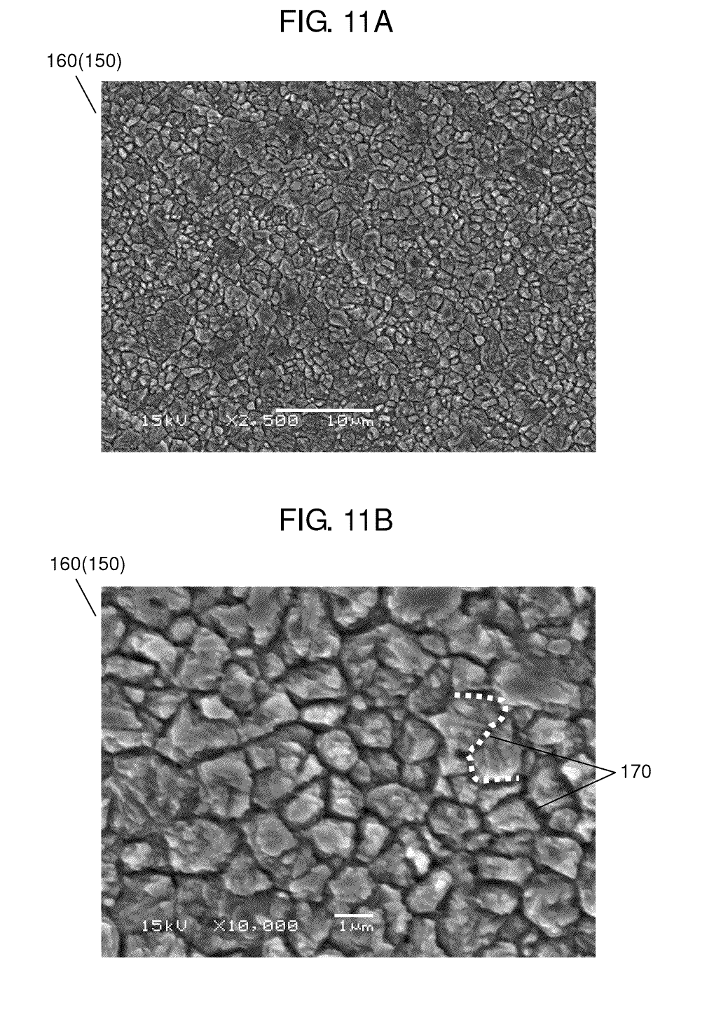

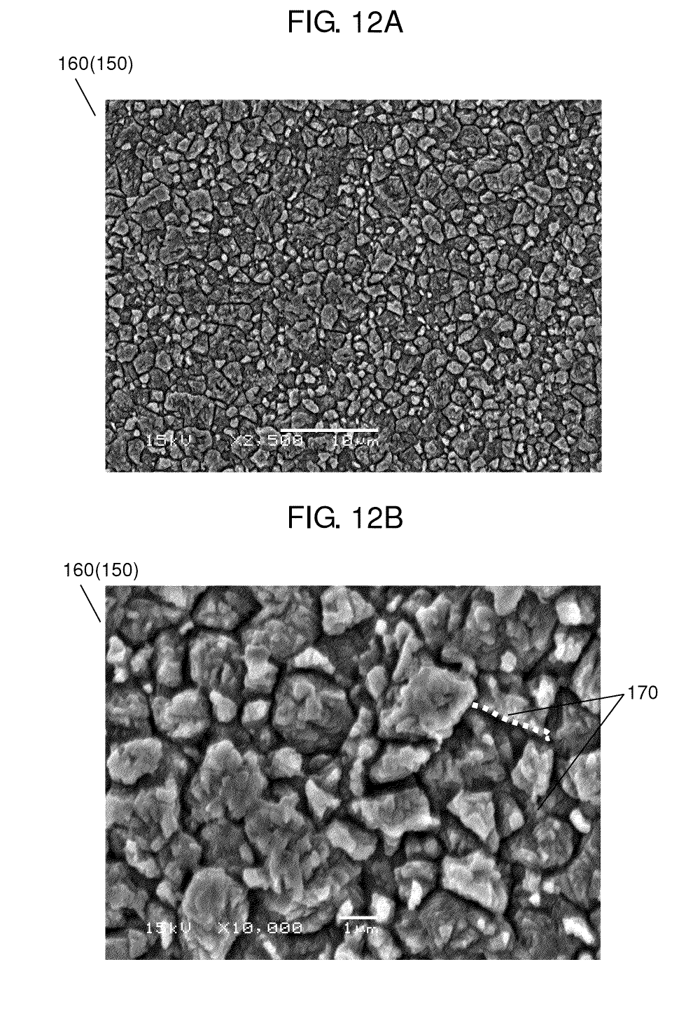

Next, a description will be given of one example of the copper foil evaluated in Table 3 and Table 4. FIGS. 10A to 12B show photograph images, viewed through a SEM, of etched surface 160 of surface-roughened copper foil 150. An etching amount of surface-roughed copper foil 150 increases in order of FIGS. 10A, 11A, and 12A.

A magnification used for FIGS. 10A, 11A, and 12A is 2500 time, and a magnification used for FIGS. 10B, 11B, and 12B is 10000 time. White dotted lines in FIGS. 10B, 11B, and 12B indicate groove portion 170 formed on etched surface 160 (or on a surface of surface-roughened copper foil 150).

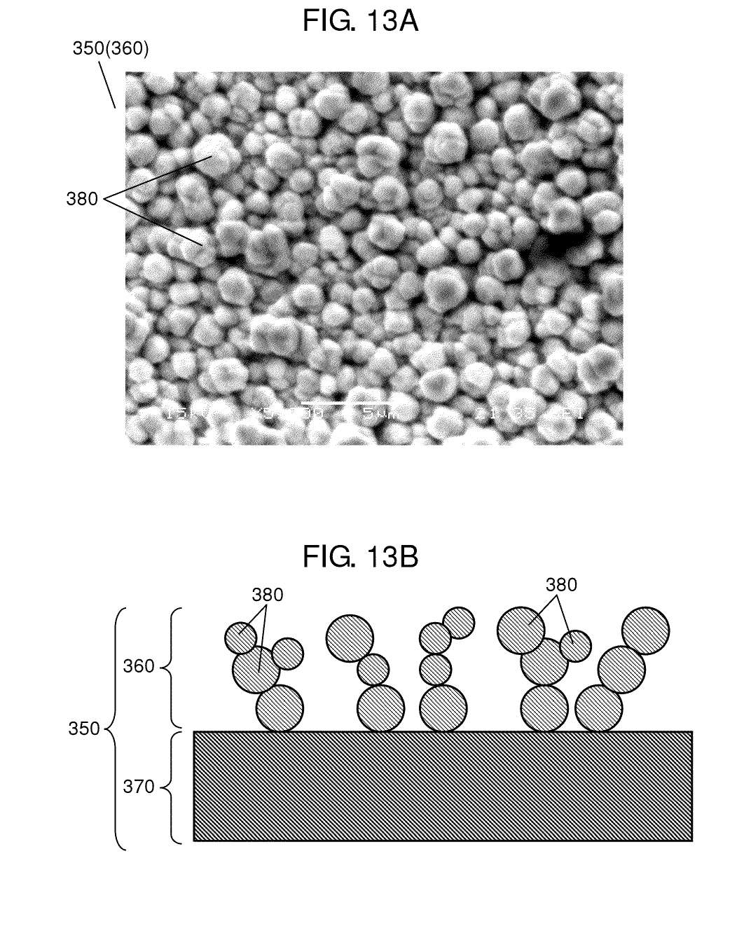

FIG. 13A shows a photograph image, viewed through a SEM, of a surface portion of a commercially available copper foil (conventional surface-roughened foil 350), and FIG. 13B is a schematic cross sectional view thereof. It is understood from FIG. 13A that protrusions 380 in a bump shape or a spherical shape are formed on a surface of conventional surface-roughened foil 350. Further, as illustrated in FIG. 13B, according to conventional surface-roughened foil 350, protrusions 380 which form a surface-roughened portion 360 are formed on core portion 370 of the copper foil and the like by applying the protrusions in a later stage or the like.

According to conventional surface-roughened foil 350 shown in FIG. 13A, the “anchor residue” tends to be caused as previously described. It is presumed that protrusions 380 serve as a source for causing anchor residue 9 as illustrated in FIG. 26B.

Furthermore, in the case of conventional surface-roughened foil 350, a plurality of protrusions 380 are strung together like beads in a thickness direction thereof, as illustrated in FIG. 13B. For this reason, when via paste 310 including protruding portions 320 is pressed at a high pressure as illustrated in FIGS. 7A and 7B, a connection portion between protrusion 380 and protrusion 380 is broken or deformed, which may adversely affect conductivity.

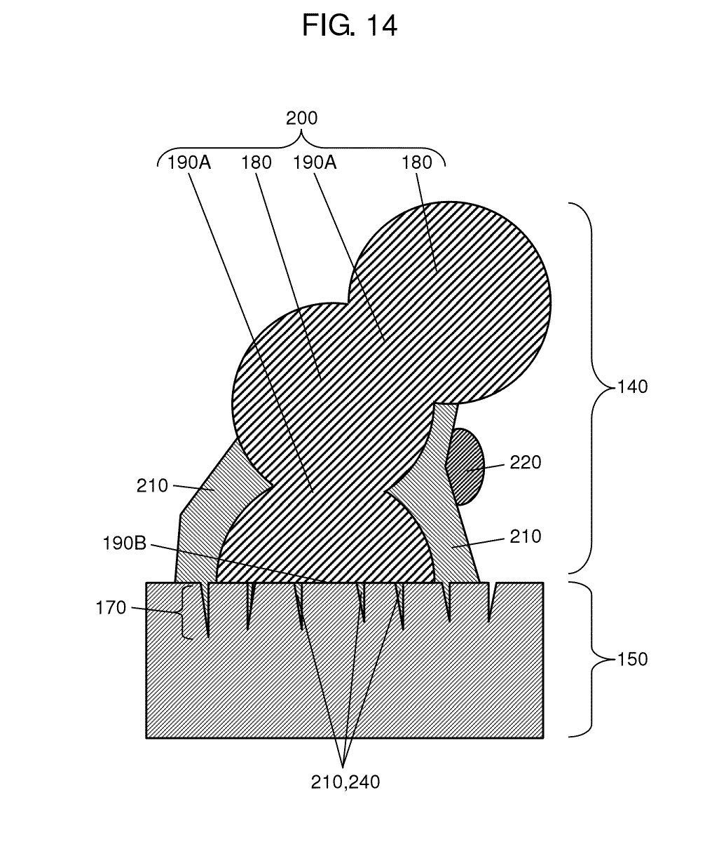

FIG. 14 is a schematic cross sectional view illustrating a connection structure between surface-roughened copper foil 150 and via-hole conductor 140. It is preferable that groove portion 170 be formed by etching on a surface of surface-roughened copper foil 150. It is also preferable to use a commercially available electrolytic copper foil as the copper foil. In addition, a surface roughness of surface-roughened copper foil 150 is a rough surface having skewness Rsk of 0 or less of a roughness curve defined by ISO 4287-1997. If a rolled copper foil is used, groove portion 170 may not be provided.

Further, in order to make Rsk of the rough surface of surface-roughened copper foil 150 formed of an electrolytic copper foil to become 0 or less, it is preferable to partially remove grain boundaries formed in a plurality of crystal grain boundaries that constitute the electrolytic copper foil. Furthermore, it is also possible to remove part of the crystal grain boundaries and further part of crystal grains, and provide closed-end gaps which are provided among a plurality of crystal grains. In such a case, Rsk can also be made as 0 or less.

In addition, in order to form the rough surface having skewness Rsk of 0 or less of a roughness curve defined by ISO 4287-1997, it is useful to form, on the surface of the electrolytic copper foil, at least one of etching grooves, a grain boundary etching portion, and a branch-shaped grain boundary etching portion, each having a width of 0.1 μm or more and 2.0 μm or less, a depth of 0.2 μm or more and 20.0 μm or less.

By selecting a method for etching or the like, the grain boundary portion of the electrolytic copper foil can be selectively removed. Accordingly, it is useful to expose, as they are, on the surface of the electrolytic copper foil, crystal grains having lower specific resistance and higher purity of copper than those of the grain boundaries. As a result, Rsk of the surface of the electrolytic copper foil becomes 0 or less.

As described above, it is possible to effectively expose the crystal grains, as they are, on the surface of the copper foil by forming a rough surface having Rsk of 0 or less of a roughness curve defined by ISO 4287-1997. In addition, the via resistance can be reduced by directly forming via-hole conductor 140 on surfaces of the crystal grains exposed on the surface of the copper foil.

It is useful to form second metal region 210 and resin portion 240 in groove portion 170. A connection area between a surface of surface-roughened copper foil 150 and copper particles 180 or second metal region 210 is widened by accommodating resin portion 240 in groove portion 170. Also, a connection area between the surface of surface-roughened copper foil 150 and copper particles 180 can be widened by accommodating second metal region 210 in groove portion 170.

As shown in FIGS. 10A to 12B, it is useful to make a shape of groove portion 170 as a surface pattern of a muskmelon (or random hexagonal pattern). With this shape, resin portions 240 accommodated in a plurality of groove portions 170 can be dispersed in further wide areas.

A groove width of groove portion 170 is preferably 0.1 μm or more and 2.0 μm or less. In the case where the groove width of groove portion 170 is less than 0.1 μm, an effect of accommodating resin portion 240 may not be provided. In addition, in the case where the groove width exceeds 2.0 μm, plane-to-plane contact among copper particles 180 may be adversely affected.

Further, a groove depth of groove portion 170 is preferably 0.2 μm or more and 20 μm or less. In the case where the groove depth is less than 0.2 μm, an effect of accommodating resin portion 240 may not be provided. In addition, in the case where the groove depth exceeds 20 μm, wiring resistance may be adversely affected. The groove depth and the groove width may be measured by viewing a cross section of a prototype through a SEM. It is useful, as required, to obtain an average value of values of a plurality positions and evaluate the average value.

In the case where surface-roughened copper foil 150 is produced by etching a surface of a commercially available plain copper foil, it is preferable to selectively remove the grain boundaries of the plain copper foil by etching. In this way, the surface of surface-roughened copper foil 150 can be made flat. In other words, referring to FIG. 14, a portion that makes plane-to-plane contact with copper particles 180 can be flattened. With this flatness, the surfaces of surface-roughened copper foil 150 can withstand a high pressing pressure, and therefore the problem described with reference to FIG. 13B can be prevented.

Meanwhile, slice etching may be conventionally performed even on a plain foil to remove a surface oxide film or the like on a copper foil. In this case, surfaces roughness prior to and subsequent to the slice etching may not be changed.

According to this embodiment, the connection areas between surface-roughened copper foil 150 and copper particles 180 or second metal regions 210 are widened by accommodating resin portion 240 in groove portion 170. Therefore, it is preferable that the copper foil be etched so that surface roughness thereof is increased. In addition, not only simply increasing the surface roughness, but also it is preferable to form a knurled surface (rough surface or roughened surface) attributable to metallic copper crystals by selectively performing deeper etching on portions of grain boundaries (crystal grain boundaries) of the copper file and removing the portions. Such a surface has a high purity of copper, has high reactivity with the solder powder, and therefore is useful for alloying or forming an intermetallic compound.

Further, it is possible to increase a purity of copper in a portion where the plane-to-plane contact with copper particles 180 is provided by etching the surface of the commercially available plain copper foil, and removing an oxide layer or grain boundaries on the surface thereof to thereby produce surface-roughened copper foil 150. With this treatment, it is possible to stabilize the contact of the portion that makes plane-to-plane contact with copper particles 180. At the same time, formation of second metal region 210 on the surface of surface-roughened copper foil 150 can be facilitated.

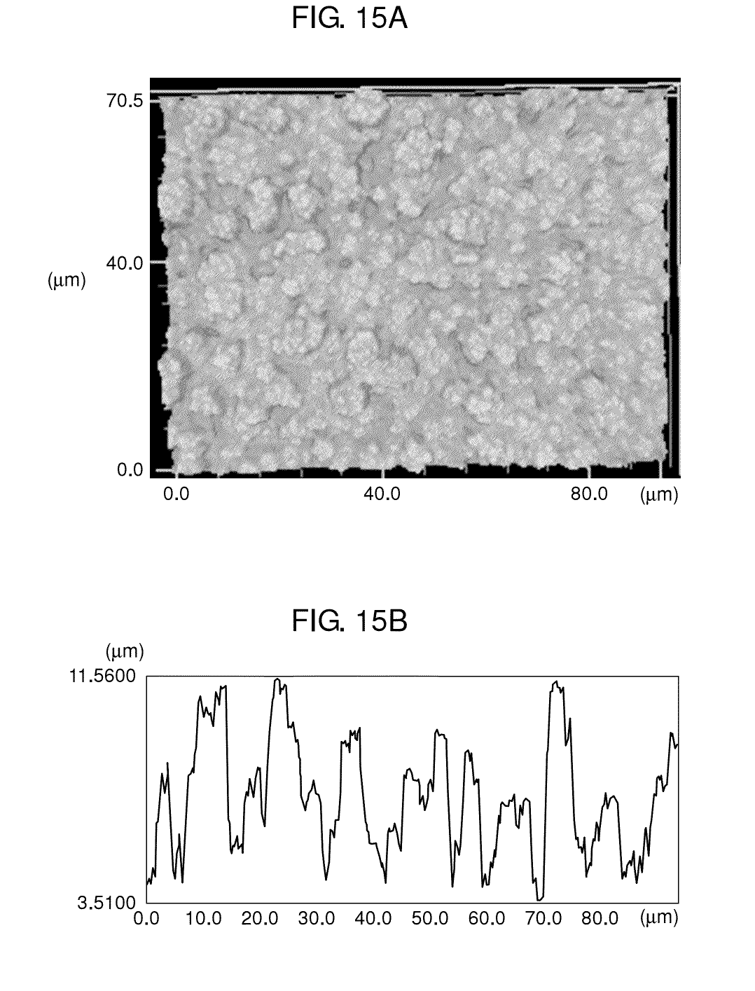

Next, one example of measurement results of surface roughness of the electrolytic copper foil used for wiring board 100 or multilayer wiring board 110 will be described with reference to FIGS. 15A to 17B.

FIG. 15A is a micrograph of a commercially available copper foil viewed through a laser microscope, and FIG. 15B is a diagram indicating surface roughness of the micrograph shown in FIG. 15A. A measured object of these drawings corresponds to the copper foil shown in FIG. 13A. As a result of measuring the surface roughness of the copper foil, using a commercially available laser microscope (VK-9500 laser microscope produced by KEYENCE CORPORATION), the surface roughness of the commercially available copper foil in a horizontal distance of 93.9390 μm is as follows. Rp (maximum height of crest) is 4.7815 μm, Rv (maximum depth of trough) is 3.6113 μm, and Rz (Rt) is 8.3927 μm. Rc (average height of element) is 6.3157 μm, Ra (arithmetic average height) is 1.6274 μm, Rsk (skewness) is 0.2834, and Rku (kurtosis) is 2.2577.

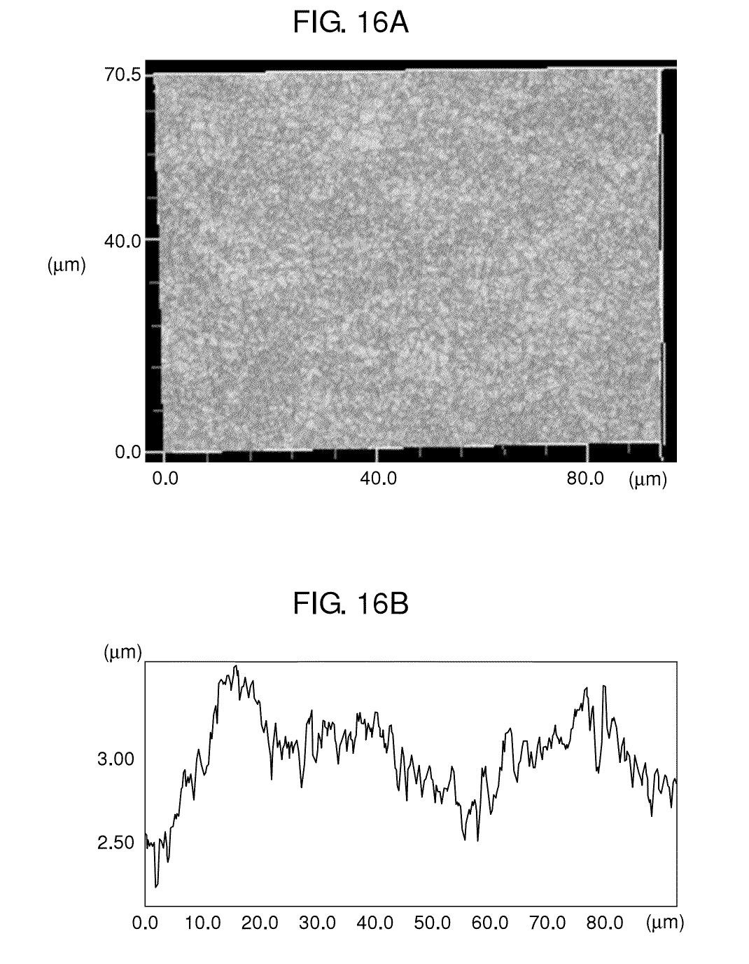

FIG. 16A is a micrograph of etched surface 160 of surface-roughened copper foil 150 viewed through the laser microscope, and FIG. 16B is a diagram indicating surface roughness of the micrograph shown in FIG. 16A. A measured object of these drawings corresponds to the copper foil shown in FIG. 10A. A result of measuring the surface roughness of the copper foil in a horizontal distance of 93.9390 μm as in the case of the commercially available copper foil is as follows. Rp is 0.5955 μm, Rv is 0.8666 μm, and Rz is 1.4621 μm. Rc is 0.8011 μm, Ra is 0.2066 μm, Rsk is −0.2948, and Rku is 3.2004.

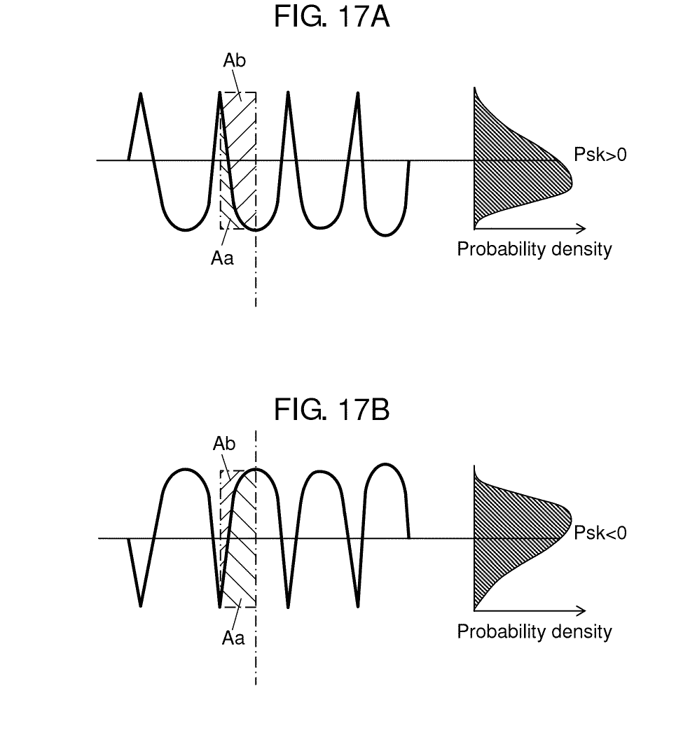

Next, Rsk (skewness) will be described with reference to FIGS. 17A and 17B. FIGS. 17A and 17B are descriptive drawings of Rsk. The roughness curve of Rsk is an average of cube of Z(x) with respect to a reference length, which is made dimensionless by cube of a root-mean-square height Rq. Specifically, Rsk is calculated by Equation (1).

$$Rsk = \frac{1}{{Rq}^{3}} [ \frac{1}{Lr} {\int }_{0}^{Lr} {Z}^{3} ( x ) d x ] \qquad ( 1 )$$

An area of a crest portion per unit length is represented by Aa, and an area of a trough is represented by Ab. As illustrated in FIG. 17A, in the case where Aa is smaller than Ab, a peak of a probability density distribution is shifted from a center toward right, and skewness Rsk becomes a positive value (>0). In contrast, as illustrated in FIG. 17B, in the case where Aa is larger than Ab, the peak of the probability density distribution is shifted from the center toward left, and skewness Rsk becomes a negative value (<0). When the probability density distribution is a normal distribution, Rsk becomes 0. Accordingly, Rsk is an index of symmetry between the crest and the trough, and therefore is an appropriate parameter for distinguish between the conventional electrolytic copper foil and the etching copper foil according to the present invention.

It is preferable that Rsk be set to 0 or less, more preferably less than 0. Further, the copper foil is the electrolytic copper foil, and Rsk is made 0 or less by forming, on the surface of the electrolytic copper foil, a plurality of etching grooves (i.e., groove portion 170 formed by etching) having a width of 0.1 μm or more and 2.0 μm or less, a depth of 0.2 μm or more and 20.0 μm or less.

Further, when the electrolytic copper foil is used and etched so that Rsk becomes 0 or less, it is possible to arrange metal portion 230 of via-hole conductor 140 as including at least one of copper (Cu) and silver (Ag), and tin (Sn) and bismuth (Bi). This is because both copper (Cu) and silver (Ag) have low resistance. However, since silver is costly, and therefore it is desirable to form metal portion 230 from copper, tin, and bismuth in a practical use as described earlier.

As described earlier, it is useful to use Rsk as an evaluation index of groove portion 170 that is formed by etching on the surface of surface-roughened copper foil 150 (wiring 120). Furthermore, by making Rsk 0 or less (preferably a negative value), the remaining residue (anchor residue 9 or the like) in etching can be reduced while adhesion to resin portion 240 can be maintained.

In other words, by making Rsk 0 or less, it is easy to accommodate resin portion 240 included in via-hole conductor 140 in groove portion 170 (and further on the etching surface) having Rsk of 0 or less. As a result, it is possible to suppress residues or spreading of resin portion 240 between surface-roughened copper foil 150 and via-hole conductor 140, when surface-roughened copper foil 150 and via-hole conductor 140 are connected together.

In addition, by making Rsk 0 or less, an anchor effect for obtaining a necessary adhesion strength can be provided while an absolute amount of a wiring material to bite into insulating resin layer 130 is reduced. Therefore, the residues during etching can be reduced while the necessary adhesion strength is maintained. Meanwhile, it is more effective as the value of Rsk is smaller than 0, such as −0.1, and further −0.2, and −0.3. However, it is practically better that Rsk is −20 or larger, and further Rsk is −10 or larger. When productivity of the electrolytic copper foil is taken into account, Rsk is preferably −5.0 or larger, more preferably −3.0 or larger. If Rsk is reduced to a value smaller than −20, adhesion with the resin material may be adversely affected. When a copper foil is used for the wiring board, it is practical to set Rsk to −3.0 or larger and smaller than 0.

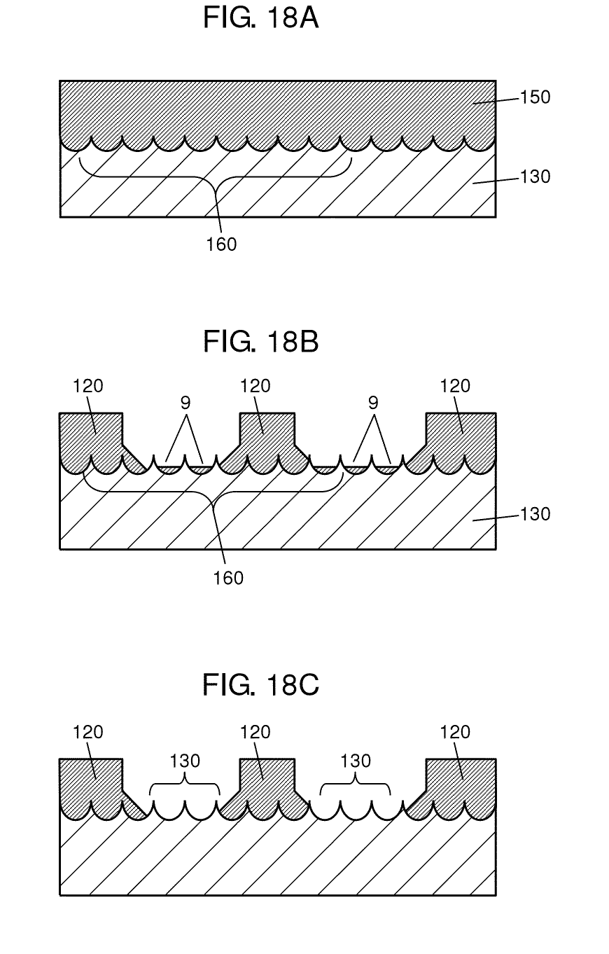

Here, with reference to FIGS. 18A to 18C, a description will be given of a state in which further fine patterns are formed by etching surface-roughened copper foil 150 having Rsk of 0 or less (further a negative value). FIGS. 18A to 18C are cross sectional views illustrating a state in which a further fine pattern is formed by etching surface-roughened copper foil 150 having Rsk of 0 or less.

FIG. 18A illustrates a cross section prior to etching. As illustrated in FIG. 18A, at least one surface of surface-roughened copper foil 150 is etched surface 160.

FIG. 18B is a cross sectional view illustrating a state in which a plurality of wirings 120 are formed by etching surface-roughened copper foil 150. Here, an etching resist, etching itself, and the like are not illustrated. Although portions which are not yet removed by etching among wirings 120 are illustrated as a kind of anchor residues 9, anchor residues 9 can be easily removed.

FIG. 18C is a cross sectional view illustrating a state in which wirings 120 are formed by etching surface-roughened copper foil 150. As illustrated in FIGS. 18B and 18C, anchor residues 9 are not caused by setting Rsk of etched surface 160 of surface-roughened copper foil 150 to 0 or less.

Since anchor residues 9 are not caused, and therefore the wiring patters will be fined easily. Here, it is useful to define a line width of wiring 120 and line spacing of wiring 120 based on a thickness of wiring 120 (or thickness of copper foil). For example, the line width of wiring 120 is preferably set to 0.5 times or more and 5.0 times or less of the thickness of wiring 120. In the case where the width of wiring 120 is smaller than 0.5 times of the thickness of wiring 120, a variation in width of wiring 120 may increase in a thickness direction. In addition, if the line width is made larger than 5.0 times, wiring density may be adversely affected.

In a similar manner, the line spacing (gap) between wirings 120 is preferably set to 0.5 times or more and 5.0 times or less of the thickness of wiring 120. In the case where the line spacing (gap) between wirings 120 is less than 0.5 times of the thickness of wiring 120, a variation in width of wiring 120 may increase in a thickness direction. In addition, if the line spacing is made larger than 5.0 times, wiring density may be adversely affected.

It is preferable that Rsk be negative (negative value), and an absolute value thereof be larger. If Rsk is a negative value, and the absolute value thereof is larger, it means that a shape of the roughened portion by etching becomes narrow and deep. The roughened surface is disposed on the insulating resin layer 130 side as illustrated in FIG. 18A. Then, as illustrated in FIG. 18B, wirings 120 are formed through a subtractive process using an etchant. In this way, by making Rsk to be negative (negative value), etching residues are difficult to be caused between the conductors as illustrated in FIG. 18C, and finer wiring can be formed. The etching residues are, for example, anchor residues 9 illustrated in FIG. 26B previously mentioned.

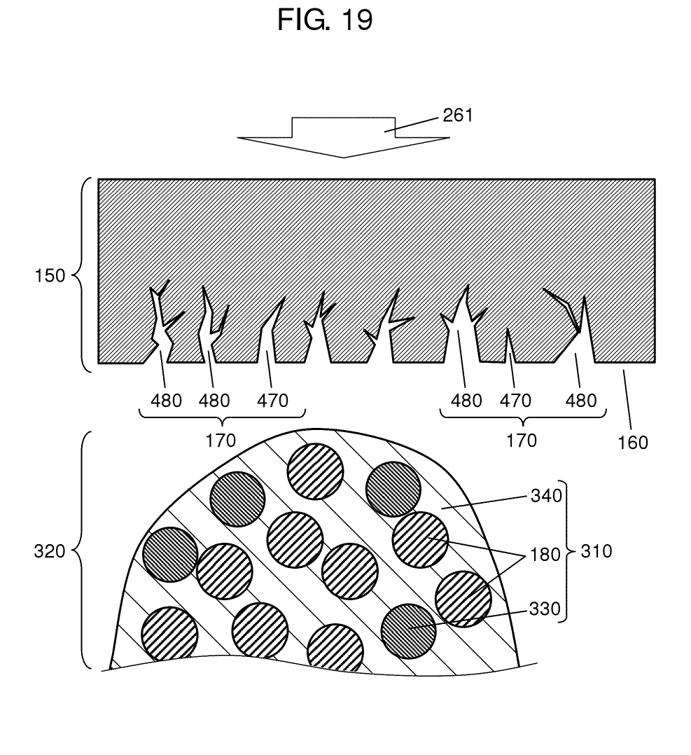

Next, with reference to FIGS. 19 to 22, a detailed description will be given of a mechanism for forming a structure illustrated in FIG. 14 through the steps described with reference to FIGS. 7A and 7B. FIG. 19 is cross sectional view illustrating a state prior to bringing a protruding portion of a via paste into pressure contact with a surface of an electrolytic copper foil which is an etching surface having skewness (Rsk) of 0 or less of a roughness curve defined by ISO 4287-1997. FIG. 19 is an enlarged view illustrating a state corresponding to FIG. 7A.

As described earlier, it is preferable to use, as surface-roughened copper foil 150 illustrated in FIG. 19, an electrolytic copper foil including an etched surface having Rsk of 0 or less of a roughness curve defined by ISO 4287-1997.

The etched surface having Rsk of 0 or less of the roughness curve defined by ISO 4287-1997 has, for example, grain boundary etched portions 470 and branch-shaped grain boundary etched portions 480 as described earlier and as illustrated in FIG. 19. Grain boundary etched portions 470 are a recess portions formed by selectively removing, by etching, the grain boundaries of the electrolytic copper foil. In addition, branch-shaped grain boundary etched portions 480 are one form of grain boundary etched portions 470, and are recessed portions formed by removing, by etching, a plurality of branched grain boundaries. By forming grain boundary etched portions 470 and branch-shaped grain boundary etched portions 480 on etched surface 160, it is possible to reduce Rsk of the roughness curve defined by ISO 4287-1997 to 0 or less.

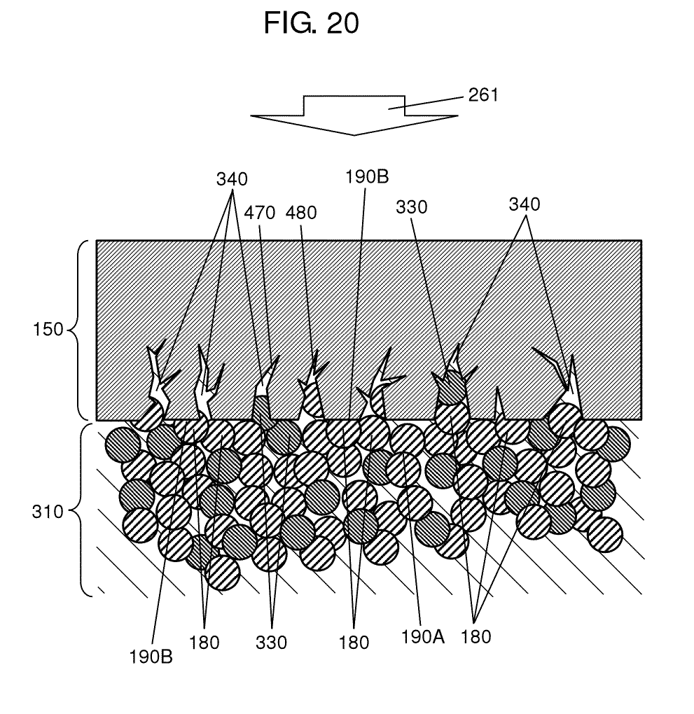

FIG. 20 is a cross sectional view illustrating a state subsequent to bringing the protruding portion of the via paste into pressure contact with the etched surface of the electrolytic copper foil having skewness Rsk of 0 or less of the roughness curve defined by ISO 4287-1997. FIG. 20 is an enlarged view illustrating a state corresponding to FIG. 7B.

Copper particles 180 and solder particles 330 included in via paste 310 are pressed against one another and adhere together. At the same time, part of them form plane-to-plane contact portion 190A. Here, plane-to-plane contact portion 190A is formed between copper particles 180, or between copper particles 180 and solder particles 330. Similarly, plane-to-plane contact portion 190B is also formed between copper particles 180 and surface-roughened copper foil 150, or between solder particles 330 and surface-roughened copper foil 150.

Copper particles 180 and solder particles 330 are partially pressed into grain boundary etched portions 470 and branch-shaped grain boundary etched portions 480 of surface-roughened copper foil 150. Furthermore, organic component 340 contained in via paste 310 penetrates into grain boundary etched portions 470 and branch-shaped grain boundary etched portions 480, thereby adhesion between surface-roughened copper foil 150 and copper particles 180 or solder particles 330 is enhanced.

Meanwhile, a variation of a thickness of surface-roughened copper foil 150 can be suppressed by etching a surface of surface-roughened copper foil 150 and making skewness Rsk of the roughness curve defined by ISO 4287-1997 to be 0 or less. This is because the grain boundary portions are removed by etching. A variation in height of protruding portion 320 of via paste 310 becomes larger as the via diameter is made smaller from 120 μm down to 60 μm. In such a case, making the variation in height (or variation in thickness) of surface-roughened copper foil 150 smaller is useful for performing uniform compressed pressure contact.

As described above, an etched surface having skewness Rsk of 0 or less of the roughness curve defined by ISO 4287-1997 is formed. With the formation of the etched surface, it is possible to increase adhesion between surface-roughened copper foil 150 and copper particles 180 or solder particles 330 by absorbing organic component 340 in groove portion 170 while an influence of the variation in height of protruding portions 320 of via paste 310 is suppressed.

Here, the surface of surface-roughened copper foil 150 illustrated in FIGS. 19 and 20 is in the same state as shown in FIGS. 10A to 12B. Further, the surface of surface-roughened copper foil 150 illustrated in FIGS. 19 and 20 has skew Rsk of −0.2948 of the roughness curve defined by ISO 4287-1997, as shown in FIGS. 16A and 16B.

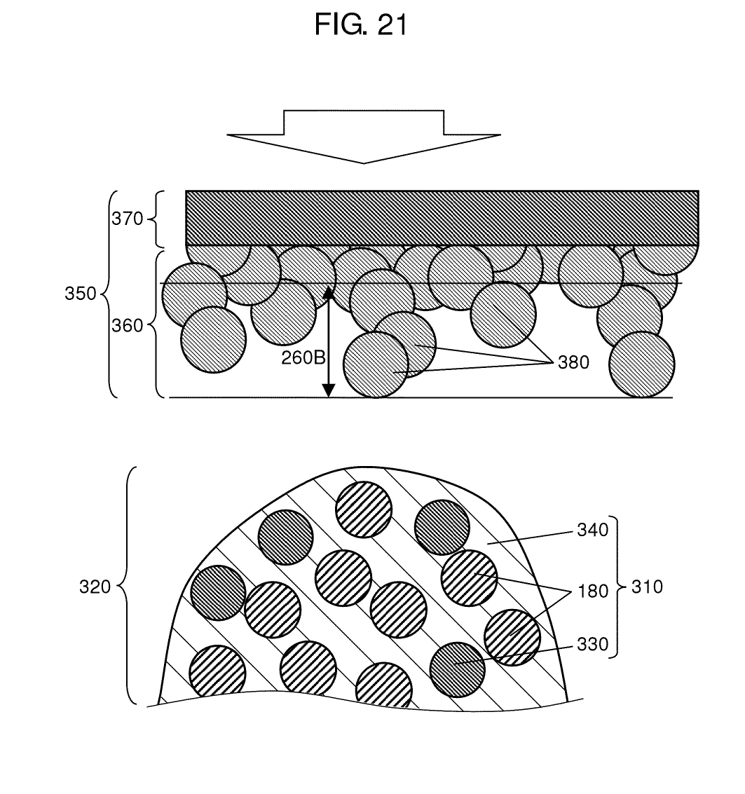

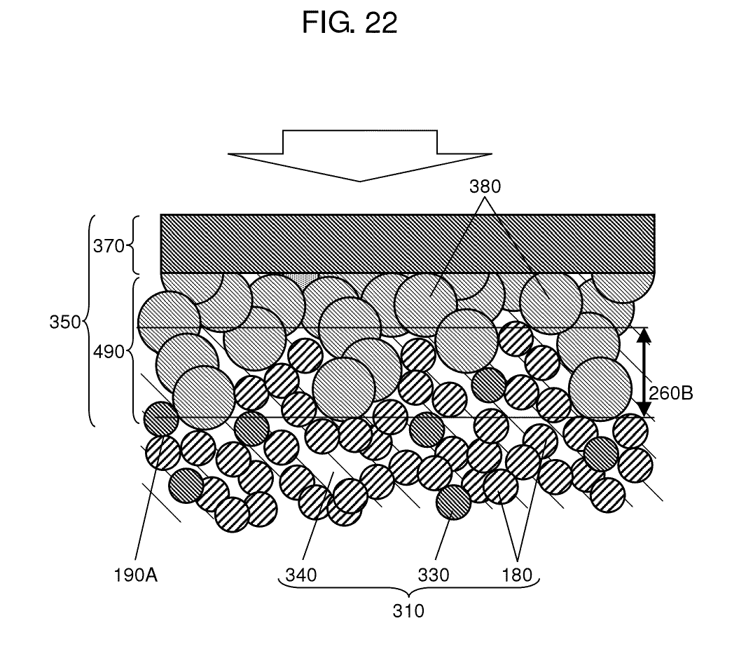

FIGS. 21 to 22 are cross sectional views illustrating a case where a conventional copper foil is used. FIG. 21 is a cross sectional view illustrating a state prior to bringing protruding portion 320 of via paste 310 into pressure contact with the surface of the conventional surface-roughened foil.

Conventional surface-roughened foil 350 described with reference to FIGS. 13A and 13B is structured of core portion 370, and roughened portion 360 which is mainly formed of protrusions 380. Therefore, surface roughness as indicated by arrow 260B is present. A surface of conventional surface-roughened foil 350 has characteristics shown in FIGS. 15A and 15B, and has skewness Rsk of 0.2843 of the roughness curve defined by ISO 4287-1997.

FIG. 22 is a cross sectional view illustrating a state subsequent to bringing protruding portion 320 of via paste 310 into pressure contact with the surface of conventional surface-roughened copper foil 350. Conventional surface-roughened foil 350 has surface roughness, and therefore copper particles 180 and solder particles 330 included in via paste 310 are pressured from each other and make intimate contact. A part of them is easily affected by the variation in height of the protruding portion of via paste 310 when plane-to-plane contact portion 190A is formed.

As the via diameter is reduced from 120 μm down to 60 μm, the variation in height of the protruding portion of via paste 310 may become larger. In the case of conventional surface-roughened foil 350, when the variation in height becomes larger, compressed pressure contact may be affected.

As described above, wiring board 100 and multilayer wiring board 110 include at least one insulating resin layer 130, wirings 120, and via-hole conductor 140. Wirings 120 are disposed via insulating resin layer 130 therebetween and formed of surface-roughened copper foil 150. Via-hole conductor 140 penetrates through insulating resin layer 130, and connects wirings 120 together. Via-hole conductor 140 has resin portion 240 and metal portion 230 including copper, tin, and bismuth. Metal portion 230 includes first metal region 200, second metal region 210, and third metal region 220. First metal region 200 includes links 195 of copper particles 180. Second metal region 210 includes, as a main component, at least one of tin, a tin-copper alloy, and a tin-copper intermetallic compound. Third metal region 220 include bismuth as a main component. The weight ratio of composition, i.e., copper:tin:bismuth, of Cu, Sn, and Bi in metal portion 230 is in a quadrilateral with vertices of A (0.37:0.567:0.063), B (0.22:0.3276:0.4524), C (0.79:0.09:0.12), and D (0.89:0.10:0.01) in a ternary plot. The surface of surface-roughened copper foil 150, which makes contact with via-hole conductor 140, is a rough surface having skewness Rsk of 0 or less of the roughness curve defined by ISO 4287-1997. In addition, second metal region 210 is partially formed on surfaces of copper particles 180 and a rough surface of surface-roughened copper foil 150.

As described above, the weight ratio of composition (Cu:Sn:Bi) of Cu, Sn, and Bi is in a region enclosed by a quadrilateral with vertices of A (0.37:0.567:0.063), B (0.22:0.3276:0.4524), C (0.79:0.09:0.12), and D (0.89:0.10:0.01) in a ternary plot. This may be stated that the weight ratio of composition (Cu:Sn:Bi) of Cu, Sn, and Bi is in a region enclosed by a quadrilateral with vertices of A (0.37:0.567:0.063), B (0.22:0.3276:0.4524), C (0.79:0.09:0.12), and D (0.89:0.10:0.01) in a triangular diagram (or triangle diagram). This is because it may be useful to express a composition of substances of an arbitrary point in a ternary component system as a triangle diagram or a triangular diagram, rather than expressing it as a unitary diagram, which is a solid solution diagram, indicating a border line or like between a liquid phase and a solid phase, or a ternary diagram which is an extension of a binary diagram showing liquidus, solidus, and the like.

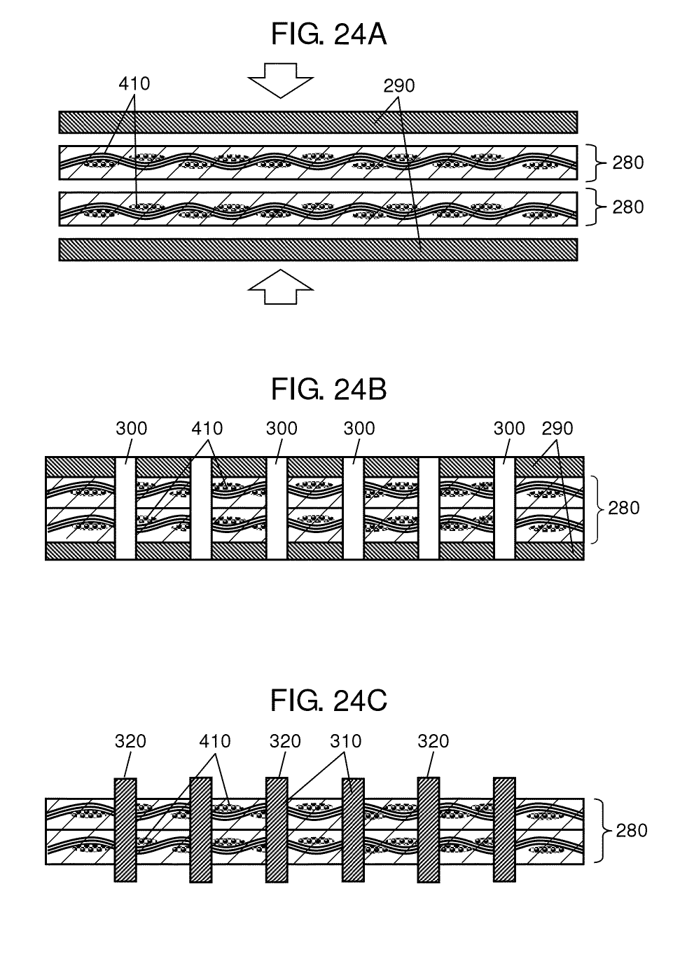

Next, one example applied to a built-up multilayer wiring board having a core substrate portion and a built-up layer portion will be described with reference to FIGS. 23A to 24C.

FIGS. 23A and 23B are cross sectional views illustrating one example applied to a built-up multilayer wiring board having a core substrate portion and built-up layer portions.

Multilayer wiring board 115 illustrated in FIG. 23A has core substrate portion 390A and built-up layer portions 440. On the other hand, multilayer wiring board 116 illustrated in FIG. 23B has core substrate portion 390B and built-up layer portions 440. Core substrate portions 390A and 390B have core via-hole conductors 400, core material 410, core wirings 420, and core insulating resin layers 430. Each of built-up layer portion 440 has built-up wirings 450 and built-up insulating resin layer(s) 460.

Core substrate portion 390A corresponds to a double-sided board, whereas core substrate portion 390B corresponds to a four-layered board. As described above, the number of layers of the core substrate portion is not limited to two layers, but it serves for the purpose if the layers simply form a center portion of the multilayer wiring board.

In core substrate portions 390A and 390B, core via-hole conductor 400 is formed of a paste via or a plated via. Core wiring 420 is formed of a patterned copper foil, copper plating, or the like. Core wiring 420 may be formed on double sides as core substrate portion 390A, but may be incorporated inside as core substrate portion 390B. Core material 410 is an unwoven fabric or a woven fabric formed of inorganic fibers such as glass fibers, or organic fibers such as aramid. Core insulating resin layer 430 is a cured material of prepreg (not illustrated) in which core material 410 is buried.

At least one of core via-hole conductors 400 is filled into a through-hole which is formed while two or more prepregs having core material 410 buried therein are laminated together, and formed in which a via paste including at least copper particles and tin-bismuth solder powder is alloyed.

In built-up layer portion 440, built-up wiring 450 is formed by copper plating or the like. It is preferable that a part of built-up wiring 450 be formed inside a via hole or a closed-end hole (not illustrated) either which is formed in built-up insulating resin layer 460.

Next, a method for producing core substrate portion 390A will be described with reference to FIGS. 24A to 24C. FIGS. 24A to 24C are cross sectional views illustrating one example of a method for manufacturing multilayer wiring boards 115 and 116, core via-hole conductor 400, and the like. Core material 410 is an unwoven fabric or a woven fabric formed of inorganic fibers such as glass fibers, or organic fibers such as aramid. A commercially available prepreg may be used as prepreg 280.

First, as illustrated in FIG. 24A, prepregs 280 are disposed to make direct contact with one another, protective films 290 are disposed outside prepregs 280 and laminated together.

Next, as illustrated in FIG. 24B, through-holes 300 are formed in prepregs 280 and protective films 290 disposed on both sides thereof. Through-holes 300 can be formed by an ordinary method using a laser or a drill. For example, two sheets of prepregs 280 having a thickness of 100 μm are laminated together. Further, PET films having a thickness of 20 μm are laminated, as protective films 290, on both sides thereof to thereby form what is illustrated in FIG. 24B. In this state, through-holes 300 having a diameter of 100 μm are formed using a drill (not illustrated). In this case, an aspect of through-hole 300 expressed by thickness/diameter is 2.

Next, as illustrated in FIG. 24C, protective films 290 are removed after through-holes 300 are filled with via paste 310. Through this process, protruding portions 320 are formed. Thereafter, by performing the step illustrated in FIG. 4A, core via-hole conductor 400 is formed, and core substrate portion 390A is produced.

Subsequently, by using an ordinary built-up method or a built-up material, built-up layer portion 440, built-up wiring 450, and the like are produced. In this way, multilayer wiring boards 115 and 116 can be manufactured in a stable manner.

### INDUSTRIAL APPLICABILITY

According to the present invention, it is possible to further reduce the cost and size of multilayer wiring boards for use in cell phones and the like, and also further enhance functionality and reliability thereof. Also, in terms of via pastes, proposing a via paste, which is most suitable for a smaller via diameter and for production of via paste reaction products, contributes to miniaturization and high reliability of the multilayer wiring boards.

### REFERENCE MARKS IN THE DRAWINGS

100 wiring board
110, 115, 116 multilayer wiring board
120 wiring
130 insulating resin layer
140 via-hole conductor
150 surface-roughened copper foil
160 etched surface
170 groove portion
180 copper particles
190A, 190B plane-to-plane contact portion
195 link
200 first metal region
210 second metal region
220 third metal region
230 metal portion
240 resin portion
250 spring
260, 260B, 261 arrow
270 conductive path
280 prepreg
290 protective film
300 through-hole
310 via paste
320 protruding portion
330 solder particle
340 organic component
350 conventional surface-roughened foil
360 surface-roughened portion
370 core portion
380 protrusion
390A, 390B core substrate portion
400 core via-hole conductor
410 core material
420 core wiring
430 core insulating resin layer
440 built-up layer portion
450 built-up wiring
460 built-up insulating resin layer
470 grain boundary etched portion
480 branch-shaped grain boundary etched portion

1. A wiring board comprising:
an insulating resin layer;
a plurality of wirings disposed through the insulating resin layer therebetween and formed of a copper foil; and
a via-hole conductor penetrating through the insulating resin layer, electrically connecting the plurality of wirings together, and including a resin portion, and a metal portion containing copper, tin, and bismuth,
wherein the metal portion includes a first metal region including a link of a plurality of copper particles, a second metal region including, as a main component, at least one of tin, a tin-copper alloy, and a tin-copper intermetallic compound, and a third metal region including bismuth as a main component,
a weight ratio of composition, which is copper:tin:bismuth in the metal portion, falls in a quadrilateral defined with vertices of A (0.37:0.567:0.063), B (0.22:0.3276:0.4524), C (0.79:0.09:0.12), and D (0.89:0.10:0.01) in a ternary plot,
a surface in contact with the via-hole conductor of the copper foil is a roughened surface having skewness Rsk of 0 or less of a roughness curve defined by ISO 4287-1997,
the plurality of copper particles partially include a plane-to-plane contact with the roughened surface, and
the second metal region is at least partially formed on a surface of the link and on the roughened surface.

2. The wiring board according to claim 1,
wherein the copper foil is an electrolytic copper foil including a plurality of crystal grains that are adjacent to one another, and
the roughened surface includes closed-end gaps formed among the plurality of crystal grains that form the electrolytic copper foil.

3. The wiring board according to claim 1,
wherein a thickness of each of the plurality of wirings is 5 μm or more and 50 μm or less,
a line width of each of the plurality of wirings is 0.5 times or more and 5.0 times or less of the thickness of each of the plurality of wirings,
a line spacing among the plurality of wirings is 0.5 times or more and 5.0 times or less of the thickness of each of the plurality of wirings, and
a diameter of the via-hole conductor is 10 μm or more and 100 μm or less.

4. The wiring board according to claim 1,
wherein the insulating resin layer is one of two or more insulating resin layers, and
the wiring board includes the two or more insulating resin layers and the three or more wirings.

5. The wiring board according to claim 1,
wherein the copper foil is an electrolytic copper foil, and
at least one of an etching groove, a grain boundary etching portion, and a branch-shaped grain boundary etching portion each having a width of 0.1 μm or more and 2.0 μm or less, a depth of 0.2 μm or more and 20.0 μm or less, is formed on a surface of the electrolytic copper foil.

6. The wiring board according to claim 1,
wherein the via-hole conductor includes 20 wt % or more and 90 wt % or less of copper.

7. A built-up multilayer wiring board comprising:
a core substrate portion formed of the wiring board according to claim 1; and
a built-up layer portion built up on the core substrate portion.

8. A method for manufacturing a wiring board, the method comprising:
forming a through-hole by perforating a prepreg, which is covered with protective films, from an outer side of one of the protective films;
filling the through-hole with a via paste;
forming protruding portions, which are the via paste partially protruding from the through-hole, by removing the protective films after filling the through-hole with the via paste;
disposing copper foils each including a roughened surface having skewness Rsk of 0 or less of a roughness curve defined by ISO 4287-1997 on surfaces of the prepreg so as to cover the protruding portions with the roughened surface;
compression-bonding the copper foils onto the surfaces of the prepreg after disposing the copper foils on the surfaces of the prepreg;
heating the copper foils, the prepreg, and the via paste while the copper foils are compression-bonded onto the surfaces of the prepreg; and
patterning the copper foils to form wirings,
wherein the via paste includes a plurality of copper particles, a plurality of tin-bismuth solder particles, and a thermally curable resin,
a weight ratio of composition, which is copper:tin:bismuth falls in a quadrilateral defined with vertices of A (0.37:0.567:0.063), B (0.22:0.3276:0.4524), C (0.79:0.09:0.12), and D (0.89:0.10:0.01) in a ternary plot,
a link of the plurality of copper particles is formed, and a plane-to-plane contact portion is formed between part of the copper particles and the copper foil, by compression-bonding the copper foils onto the surfaces of the prepreg, and
a first metal region including the link; a second metal region including, as a main component, at least one of tin, a tin-copper alloy, and a tin-copper intermetallic compound, and formed between a surface of the link and the roughened surface; and a third metal region including bismuth as a main component are formed, by heating the copper foils, the prepreg, and the via paste at a temperature equal to or higher than a eutectic temperature of the solder particles for melting the solder particles.

9. The method for manufacturing a wiring board according to claim 8,
wherein the prepreg includes a woven fabric or an unwoven fabric as a core material, and
the through-hole is formed while two or more sheets of the prepreg are laminated.

10. The method for manufacturing a wiring board according to claim 8,
wherein when the copper foils are compression-bonded onto the surfaces of the prepreg, the prepreg is heated to a temperature or more at which an uncured resin layer included in the prepreg can be cured, but less than a temperature of a melting point of the solder particles.

11. The method for manufacturing a wiring board according to claim 8,
wherein when the copper foils, the prepreg, and the via paste are heated, the solder particles are partially melted at a temperature ranging from a eutectic temperature of the solder particles to a eutectic temperature plus 10° C., inclusive, and
the copper foils, the prepreg, and the via paste are subsequently heated at a temperature ranging from the eutectic temperature plus 20° C. to a temperature of 300° C., inclusive.
